(19) United States
(12) Patent Application Publication
(10) Pub. No.: US 2024/0276829 A1
(43) Pub. Date: Aug. 15, 2024

(54) DISPLAY DEVICE

(71) Applicant: Samsung Display Co., Ltd., Yongin-si (KR)

(72) Inventors: KYUNGHOE LEE, Yongin-si (KR); CHEOL-GON LEE, Yongin-si (KR); MUKYUNG JEON, Yongin-si (KR)

(21) Appl. No.: 18/506,035

(22) Filed: Nov. 9, 2023

(30) Foreign Application Priority Data
Feb. 14, 2023 (KR) 10-2023-0019201

(51) Int. Cl. H10K 59/40; G06F 3/041; G06F 3/044; G09G 3/3233; H10K 39/00; H10K 39/34

(52) U.S. Cl. CPC H10K 59/40; G06F 3/04164; G06F 3/0446; G09G 3/3233; H10K 39/34; H10K 39/501; G09G 2300/0819; G09G 2300/0842; G09G 2300/0861

(57) ABSTRACT

A display device includes: a display layer including a plurality of light emitting areas, and a plurality of sensing areas; and a sensor layer on the display layer, and including: a first sensing electrode including: a plurality of sensing patterns; and a connection pattern connected to the plurality of sensing patterns; and a second sensing electrode. Each of the plurality of sensing patterns includes: a first-first line extending in a first direction; and a second-first line extending in a second direction crossing the first direction. At least one of the connection pattern or the second sensing electrode includes a cross line extending in a direction different from the first and second directions.

### CROSS REFERENCE TO RELATED APPLICATION

The present application claims priority to and the benefit of Korean Patent Application No. 10-2023-0019201, filed on Feb. 14, 2023, in the Korean Intellectual Property Office, the entire disclosure of which is incorporated by reference herein.

### BACKGROUND

### 1. Field

Aspects of embodiments of the present disclosure relate to a display device having improved sensing performance.

### 2. Description of the Related Art

Display devices provide a variety of functions to communicate organically with users, such as displaying images to provide information to a user or sensing a user input. In recent years, the display devices include various functions to sense information, such as biometric information, of the user. As methods of sensing information of the user, a capacitance method that senses a variation in a capacitance between electrodes, an optical method that senses an incident light using an optical sensor, an ultrasonic method that senses vibrations using a piezoelectric material, or the like may be used.

The above information disclosed in this Background section is for enhancement of understanding of the background of the present disclosure, and therefore, it may contain information that does not constitute prior art.

### SUMMARY

One or more embodiments of the present disclosure are directed to a display device having improved sensing performance.

According to one or more embodiments of the present disclosure, a display device includes: a display layer including a plurality of light emitting areas, and a plurality of sensing areas; and a sensor layer on the display layer, and including: a first sensing electrode including: a plurality of sensing patterns; and a connection pattern connected to the plurality of sensing patterns; and a second sensing electrode. Each of the plurality of sensing patterns includes: a first-first line extending in a first direction; and a second-first line extending in a second direction crossing the first direction. At least one of the connection pattern or the second sensing electrode includes a cross line extending in a direction different from the first and second directions.

In an embodiment, each of the plurality of light emitting areas and each of the plurality of sensing areas may have a quadrangular shape defined by corresponding first sides extending in the first direction, and corresponding second sides extending in the second direction.

In an embodiment, the plurality of light emitting areas may include: a plurality of first light emitting areas; a plurality of second light emitting areas; and a plurality of third light emitting areas. The plurality of first light emitting areas and the plurality of third light emitting areas may be alternately and repeatedly located one by one along the first direction, and the plurality of second light emitting areas may be consecutively located along the first direction. The plurality of second light emitting areas may include a first-second light emitting area, a second-second light emitting area, and a third-second light emitting area, which may be consecutively and repeatedly located along the first direction. A first sensing area from among the plurality of sensing areas may be located between the first-second light emitting area and the second-second light emitting area, and a second sensing area from among the plurality of sensing areas may be located in an area spaced from the second-second light emitting area, with the third-second light emitting area interposed therebetween.

In an embodiment, the first sensing area and the second sensing area may be closest to each other from among the plurality of sensing areas.

In an embodiment, a first distance between the first-second light emitting area and the second-second light emitting area may be equal to or greater than a second distance between the second-second light emitting area and the third-second light emitting area.

In an embodiment, a first portion of the connection pattern and a second portion of the second sensing electrode may be located between the first sensing area and the first-second light emitting area. A third portion of the connection pattern and a fourth portion of the second sensing electrode may be located between the second-second light emitting area and the third-second light emitting area. A first distance between the first portion and the second portion may be different from a second distance between the third portion and the fourth portion in a plan view.

In an embodiment, a fifth portion of the connection pattern and a sixth portion of the second sensing electrode may be located between one first light emitting area from among the plurality of first light emitting areas and one third light emitting area from among the plurality of third light emitting areas, and a third distance between the fifth portion and the sixth portion may be different from at least one of the first distance or the second distance in a plan view.

In an embodiment, the display layer may include: a plurality of first electrodes corresponding to the plurality of light emitting areas and the plurality of sensing areas; a first functional layer on the plurality of first electrodes, and commonly corresponding to the plurality of light emitting areas and the plurality of sensing areas; a plurality of light emitting layers on the first functional layer, and corresponding to the plurality of light emitting areas, respectively; a plurality of photoelectric conversion layers on the first functional layer, and corresponding to the plurality of sensing areas, respectively; a second functional layer on the plurality of light emitting layers and the plurality of photoelectric conversion layers, and commonly corresponding to the plurality of light emitting areas and the plurality of sensing areas; and a second electrode on the second functional layer.

In an embodiment, the display layer may further include an auxiliary layer commonly located between the first functional layer and the light emitting layer of the first-second light emitting area, between the first functional layer and the light emitting layer of the second-second light emitting area, and between the first functional layer and the photoelectric conversion layer of the first sensing area.

In an embodiment, the connection pattern may include a first connection line extending in the first direction, and a second connection line extending in the second direction. The second sensing electrode may include a first-second line extending in the first direction, and a second-second line extending in the second direction. The connection pattern may be located at a layer different from that of the second sensing electrode and the plurality of sensing patterns. The connection pattern may overlap with the second sensing electrode in a plan view, and the connection pattern and the second sensing electrode may be insulated from each other.

In an embodiment, the connection pattern may further include a first cross line electrically connected to the first connection line and the second connection line, and extending in a first cross direction different from the first and second directions. The first cross line may overlap with the second sensing electrode in a plan view. In an embodiment, the second sensing electrode may not overlap with the first connection line and the second connection line in a plan view, and the second sensing electrode may have an opening corresponding to the first connection line and the second connection line.

In an embodiment, the second sensing electrode may further include a second cross line electrically connected to the first-second line and the second-second line, and extending in a second cross direction crossing the first cross direction. The first cross line may overlap with the second cross line in a plan view.

In an embodiment, an angle between the first cross line and the second cross line may be greater than or equal to about 45 degrees, and smaller than or equal to about 135 degrees.

In an embodiment, at least one of the first cross line or the second cross line may include: an overlap portion located at a portion where the first cross line overlaps with and crosses the second cross line; and a connection portion adjacent to the overlap portion. The overlap portion may have a width different from a width of the connection portion.

In an embodiment, at least one of the first cross line or the second cross line may have a width different from a width of the first connection line.

According to one or more embodiments of the present disclosure, a display device includes: a display layer including a plurality of light emitting areas, and a plurality of sensing areas; and a sensor layer on the display layer, and including: a first sensing electrode including: a plurality of sensing patterns; and a connection pattern connected to the plurality of sensing patterns; and a second sensing electrode. A first portion of the connection pattern and a second portion of the second sensing electrode are located between a light emitting area from among the light emitting areas and a sensing area from among the sensing areas adjacent to the light emitting area in a first direction. Each of the first portion and the second portion extends in a second direction crossing the first direction, and the first portion and the second portion are spaced from each other in a plan view.

In an embodiment, the connection pattern may further include a first cross line extending from the first portion in a first cross direction crossing the first and second directions, and the first cross line may overlap with the second sensing electrode in a plan view.

In an embodiment, the second sensing electrode may further include a second cross line extending from the second portion in a second cross direction crossing the first cross direction, and the first cross line may overlap with the second cross line in a plan view.

In an embodiment, an angle between the first cross line and the second cross line may be greater than or equal to about 45 degrees, and smaller than or equal to about 135 degrees.

In an embodiment, a third portion of the connection pattern and a fourth portion of the second sensing electrode may be located between two light emitting areas that are adjacent to each other in the first direction from among the plurality of light emitting areas, and a first distance in the first direction between the first portion and the second portion may be different from a second distance between the third portion and the fourth portion.

In an embodiment, the plurality of light emitting areas may include: a plurality of first light emitting areas; a plurality of second light emitting areas; and a plurality of third light emitting areas. The plurality of first light emitting areas and the plurality of third light emitting areas may be alternately and repeatedly located one by one along the first direction, and the plurality of second light emitting areas may be consecutively located along the first direction. The plurality of second light emitting areas may include a first-second light emitting area, a second-second light emitting area, and a third-second light emitting area consecutively and repeatedly located along the first direction. A first sensing area from among the plurality of sensing areas may be located between the first-second light emitting area and the second-second light emitting area, and a second sensing area from among the plurality of sensing areas may be located in an area spaced from the second-second light emitting area with the third-second light emitting area interposed therebetween.

In an embodiment, the display layer may include: a plurality of first electrodes corresponding to the plurality of light emitting areas and the plurality of sensing areas; a first functional layer on the plurality of first electrodes, and commonly corresponding to the plurality of light emitting areas and the plurality of sensing areas; a plurality of light emitting layers on the first functional layer, and respectively corresponding to the plurality of light emitting areas; a plurality of photoelectric conversion layers on the first functional layer, and respectively corresponding to the plurality of sensing areas; a second functional layer on the plurality of light emitting layers and the plurality of photoelectric conversion layers, and commonly corresponding to the plurality of light emitting areas and the plurality of sensing areas; and a second electrode on the second functional layer.

In an embodiment, the display layer may further include an auxiliary layer commonly located between the first functional layer and the light emitting layer of the first-second light emitting area, between the first functional layer and the light emitting layer of the second-second light emitting area, and between the first functional layer and the photoelectric conversion layer of the first sensing area.

According to one or more embodiments of the present disclosure, the first sensing electrode may include the sensing patterns and the connection pattern. The sensing patterns may include mesh lines extending in the first and second directions. At least one of the connection pattern or the second sensing electrode, which receive different signals from each other, may extend in a direction different from the first and second directions at the portion where the connection pattern and the second sensing electrode overlap with each other when viewed in the plane (e.g., in a plan view). Accordingly, the portion where two lines extending in the first direction overlap with each other or the portion where two lines extending in the second direction overlap with each other may be removed. In this case, a dispersion of the overlapping area, which is caused by the overlapping of the two lines extending in the same direction, may be reduced or eliminated. Thus, variations in sensing sensitivity due to a difference in a parasitic capacitance caused by the dispersion of the overlapping area may be eliminated, minimized, or reduced.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 is a block diagram of a display device according to an embodiment of the present disclosure;

FIG. 3 is a block diagram of a display layer and a display driver according to an embodiment of the present disclosure;

FIG. 4 is a block diagram of a sensor layer and a sensor driver according to an embodiment of the present disclosure;

FIG. 5 is an equivalent circuit diagram of a pixel and a sensor according to an embodiment of the present disclosure;

FIG. 6A is a cross-sectional view of a display device according to an embodiment of the present disclosure;

FIG. 6B is a cross-sectional view of a portion of a display layer according to an embodiment of the present disclosure;

FIG. 7 is an enlarged plan view of the area AA′ of FIG. 4;

FIG. 8A is an enlarged plan view of the area BB′ of FIG. 7;

FIG. 8B is an enlarged plan view of the area BB′ of FIG. 7 according to an embodiment of the present disclosure;

FIG. 9A is an enlarged plan view of the area CC′ of FIG. 4;

FIG. 9B is an enlarged plan view of the area CC′ of FIG. 4;

FIG. 10 is an enlarged plan view of the area DD′ of FIGS. 9A and 9B;

FIG. 11 is an enlarged plan view of the area EE′ of FIG. 10 according to an embodiment of the present disclosure;

FIG. 12 is an enlarged plan view of the area EE′ of FIG. 10 according to an embodiment of the present disclosure;

FIG. 13 is an enlarged plan view of the area EE′ of FIG. 10 according to an embodiment of the present disclosure;

FIG. 14 is an enlarged plan view of the area EE′ of FIG. 10 according to an embodiment of the present disclosure;

FIG. 15 is an enlarged plan view of the area EE′ of FIG. 10 according to an embodiment of the present disclosure;

FIG. 16 is an enlarged plan view of the area EE′ of FIG. 10 according to an embodiment of the present disclosure; and

FIG. 17 is an enlarged plan view of the area EE′ of FIG. 10 according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

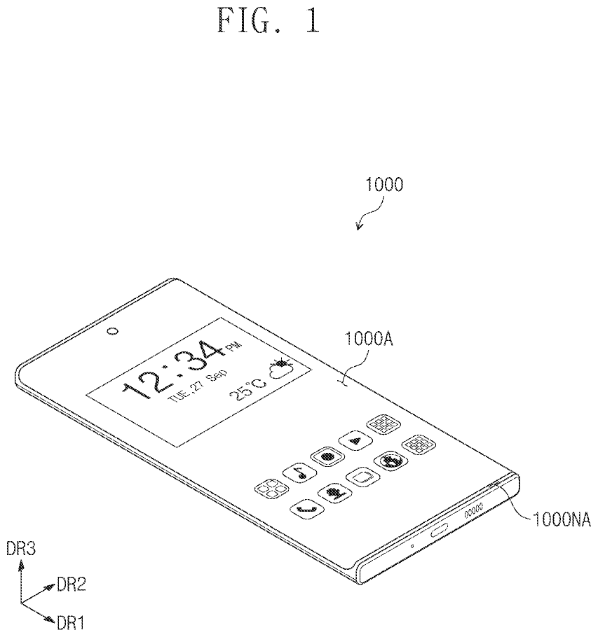

FIG. 1 is a perspective view of a display device 1000 according to an embodiment of the present disclosure.

Referring to FIG. 1, the display device 1000 may be activated in response to electrical signals. For example, the display device 1000 may be a mobile phone, a foldable mobile phone, a notebook computer, a television, a tablet computer, a car navigation unit (e.g., a car navigator), a game unit (e.g., a game console), or a wearable device. However, the present disclosure is not limited thereto or thereby. For convenience, in FIG. 1, a mobile phone is shown as a representative example of the display device 1000.

The display device 1000 may include an active area 1000A and a peripheral area 1000NA, which are defined therein. The display device 1000 may display an image through the active area 1000A. The active area 1000A may include a surface defined by a first direction DR1 and a second direction DR2. The peripheral area 1000NA may surround (e.g., around a periphery of) the active area 1000A.

A thickness direction of the display device 1000 may be parallel to or substantially parallel to a third direction DR3 crossing (e.g., intersecting) the first direction DR1 and the second direction DR2. Accordingly, front (e.g., upper) and rear (e.g., lower) surfaces of each member of the display device 1000 may be defined with respect to the third direction DR3.

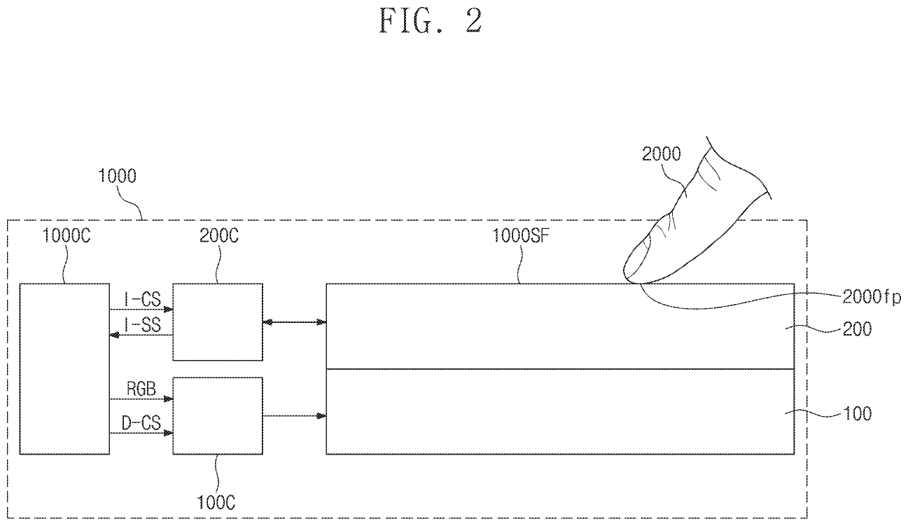

FIG. 2 is a block diagram of the display device 1000 according to an embodiment of the present disclosure.

Referring to FIG. 2, the display device 1000 may include a display layer 100, a sensor layer 200, a display driver 100C, a sensor driver 200C, and a main driver 1000C.

The display layer 100 may have a configuration that generates or substantially generates an image. The display layer 100 may be a light emitting kind of display layer. For example, the display layer 100 may be an organic light emitting display layer, an inorganic light emitting display layer, an organic-inorganic light emitting display layer, a quantum dot display layer, a micro-LED display layer, or a nano-LED display layer. In addition, the display layer 100 may include a sensor that senses light reflected by a fingerprint 2000fp of a user, or a sensor that responds to the light.

The sensor layer 200 may be disposed on the display layer 100. The sensor layer 200 may sense an external input 2000 applied to a surface 1000SF of the display device 1000 from the outside. The external input 2000 may include all suitable input manners that cause a change in a capacitance. For example, the sensor layer 200 may sense an input generated by an active-kind of input manner for providing a driving signal, as well as a passive-kind of input manner such as a user's body (e.g., a user's finger).

The main driver 1000C may control the overall operations of the display device 1000. For example, the main driver 1000C may control operations of the display driver 100C and the sensor driver 200C. The main driver 1000C may include at least one microprocessor, and in some embodiments, may further include a graphics controller. The main driver 1000C may be referred to as an application processor, a central processing unit (CPU), or a main processor.

The display driver 100C may drive the display layer 100. The display driver 100C may receive image data RGB and a control signal D-CS from the main driver 1000C. The control signal D-CS may include a variety of suitable signals. As an example, the control signal D-CS may include an input vertical synchronization signal, an input horizontal synchronization signal, a main clock, a data enable signal, and/or the like. The display driver 100C may generate a vertical synchronization signal and a horizontal synchronization signal in response to the control signal D-CS to control a timing at which signals are applied to the display layer 100.

The sensor driver 200C may drive the sensor layer 200. The sensor driver 200C may receive a control signal I-CS from the main driver 1000C. The control signal I-CS may include a mode determination signal to determine a driving mode of the sensor driver 200C, and a clock signal.

The sensor driver 200C may calculate coordinate information of the input based on signals applied thereto from the sensor layer 200, and may provide a coordinate signal I-SS having the coordinate information to the main driver 1000C. The main driver 1000C may perform an operation corresponding to the user's input based on the coordinate signal I-SS. For example, the main driver 1000C may drive the display driver 100C, such that an image of a new application may be displayed on the display layer 100.

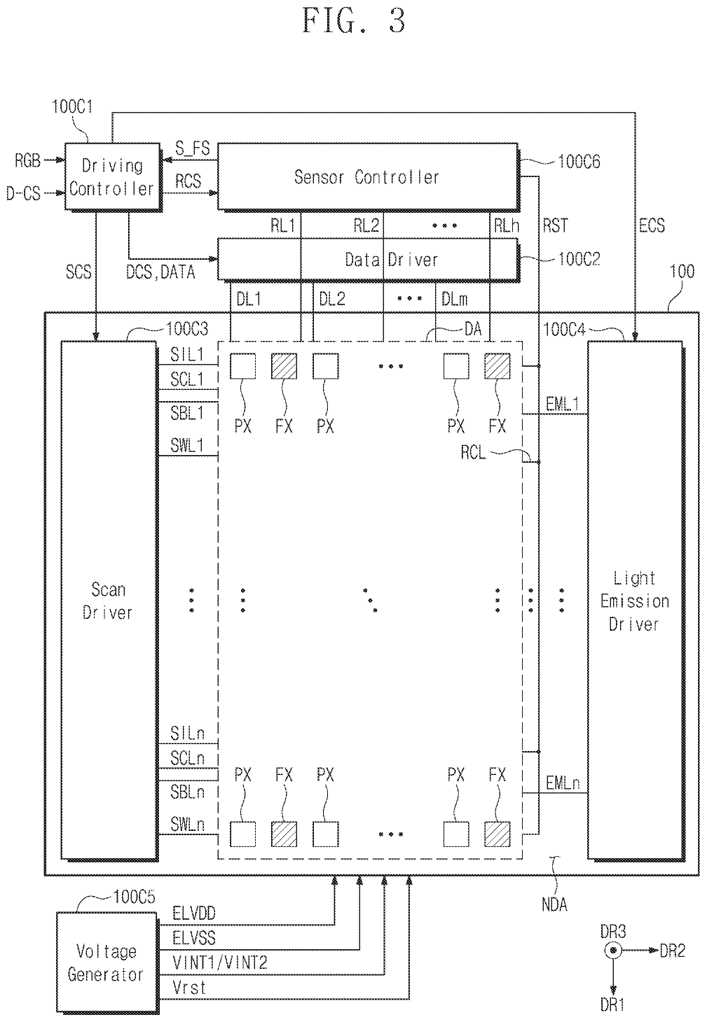

FIG. 3 is a block diagram of the display layer 100 and the display driver 100C according to an embodiment of the present disclosure.

Referring to FIGS. 2 and 3, the display driver 100C may include a driving controller 100C1, a data driver 100C2, a scan driver 100C3, a light emission driver 100C4, a voltage generator 100C5, and a sensor controller 100C6.

The display layer 100 may include a display area DA corresponding to the active area 1000A (e.g., refer to FIG. 1), and a non-display area NDA corresponding to the peripheral area 1000NA.

The display layer 100 may include a plurality of pixels PX disposed in the display area DA, and a plurality of sensors FX disposed in the display area DA. The display layer 100 may further include initialization scan lines SIL1 to SILn, compensation scan lines SCL1 to SCLn, write scan lines SWL1 to SWLn, black scan lines SBL1 to SBLn, light emission control lines EML1 to EMLn, data lines DL1 to DLm, and read-out lines RL1 to RLh. Here, “n”, “m”, and “h” are natural numbers.

The initialization scan lines SIL1 to SILn, the compensation scan lines SCL1 to SCLn, the write scan lines SWL1 to SWLn, the black scan lines SBL1 to SBLn, and the light emission control lines EML1 to EMLn may extend in the second direction DR2. The initialization scan lines SIL1 to SILn, the compensation scan lines SCL1 to SCLn, the write scan lines SWL1 to SWLn, the black scan lines SBL1 to SBLn, and the light emission control lines EML1 to EMLn may be arranged along the first direction DR1, and may be spaced apart from each other. The data lines DL1 to DLm and the read-out lines RL1 to RLh may extend in the first direction DR1, and may be arranged to be spaced apart from each other along the second direction DR2.

The pixels PX may be electrically connected to the initialization scan lines SIL1 to SILn, the compensation scan lines SCL1 to SCLn, the write scan lines SWL1 to SWLn, the black scan lines SBL1 to SBLn, the light emission control lines EML1 to EMLn, and the data lines DL1 to DLm. As an example, each of the pixels PX may be electrically connected to four scan lines. However, the number of the scan lines connected to each of the pixels PX is not limited thereto or thereby.

The sensors FX may be electrically connected to the read-out lines RL1 to RLh. One sensor FX may be electrically connected to one scan line (e.g., one write scan line from among the write scan lines SWL1 to SWLn), but the present disclosure is not limited thereto or thereby. The number of the scan lines connected to each of the sensors FX may be variously modified as needed or desired.

In an embodiment, the number of the read-out lines RL1 to RLh may correspond to half (½) of the number of the data lines DL1 to DLm, but the present disclosure is not limited thereto or thereby. As another example, the number of the read-out lines RL1 to RLh may correspond to ¼ or ⅛ of the number of the data lines DL1 to DLm.

The driving controller 100C1 may receive the image data RGB and the control signal D-CS. The driving controller 100C1 may convert a data format of the image data RGB to a data format appropriate for an interface between the data driver 100C2 and the driving controller 100C1 to generate an image data signal DATA. The driving controller 100C1 may generate a first control signal SCS, a second control signal ECS, a third control signal DCS, and a fourth control signal RCS.

The data driver 100C2 may receive the third control signal DCS and the image data signal DATA from the driving controller 100C1. The data driver 100C2 may convert the image data signal DATA to data signals, and may output the data signals to the data lines DL1 to DLm described in more detail below. The data signals may be analog voltages corresponding to grayscale values of the image data signal DATA.

The scan driver 100C3 may receive the first control signal SCS from the driving controller 100C1. The scan driver 100C3 may output scan signals to the scan lines in response to the first control signal SCS. In response to the first control signal SCS, the scan driver 100C3 may output initialization scan signals to the initialization scan lines SIL1 to SILn, and may output compensation scan signals to the compensation scan lines SCL1 to SCLn. In addition, in response to the first control signal SCS, the scan driver 100C3 may output write scan signals to the write scan lines SWL1 to SWLn, and may output black scan signals to the black scan lines SBL1 to SBLn.

The scan driver 100C3 may be disposed in the non-display area NDA of the display layer 100, but the present disclosure is not limited thereto or thereby. As an example, at least a portion of the scan driver 100C3 may be disposed in the display area DA.

The light emission driver 100C4 may be disposed in the non-display area NDA of the display layer 100. The light emission driver 100C4 may receive the second control signal ECS from the driving controller 100C1. The light emission driver 100C4 may output light emission control signals to the light emission control lines EML1 to EMLn in response to the second control signal ECS. According to an embodiment, as another example, the scan driver 100C3 may be connected to the light emission control lines EML1 to EMLn. In this case, the light emission driver 100C4 may be omitted, and the scan driver 100C3 may output the light emission control signals to the light emission control lines EML1 to EMLn.

The voltage generator 100C5 may generate voltages used to operate the display layer 100. In an embodiment, the voltage generator 100C5 may generate a first driving voltage ELVDD, a second driving voltage ELVSS, a first initialization voltage VINT1, a second initialization voltage VINT2, and a reset voltage Vrst.

The sensor controller 100C6 may receive the fourth control signal RCS from the driving controller 100C1.

The sensor controller 100C6 may receive sensing signals from the read-out lines RL1 to RLh in response to the fourth control signal RCS. The sensor controller 100C6 may process the sensing signals from the read-out lines RL1 to RLh, and may provide processed sensing signals S_FS to the driving controller 100C1.

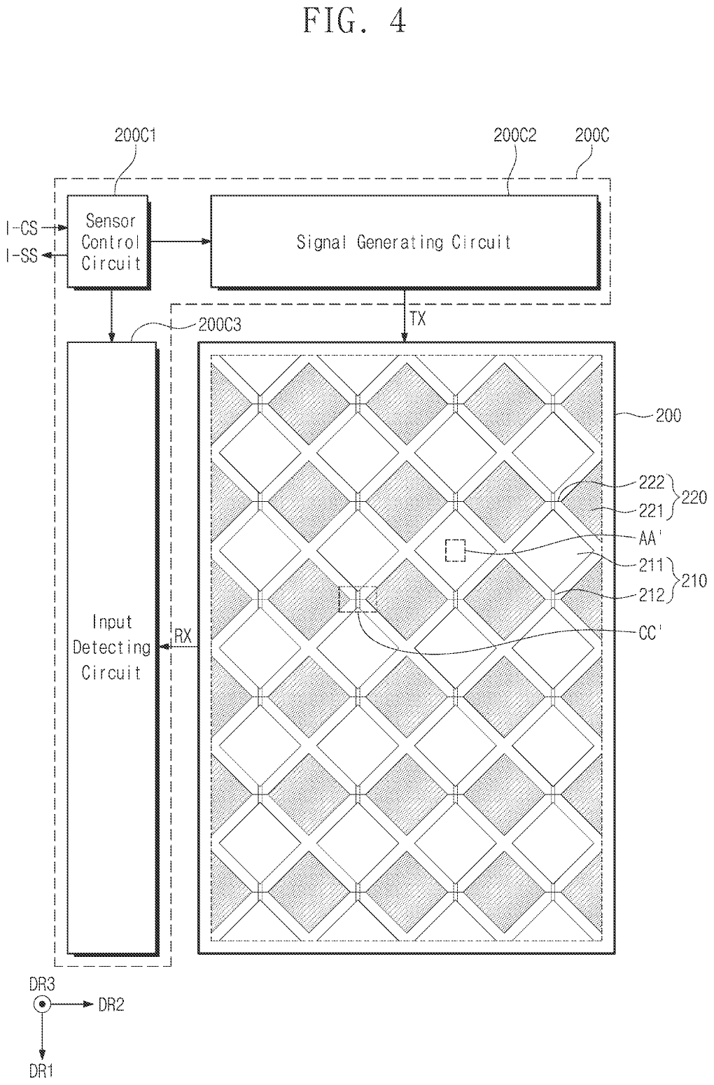

FIG. 4 is a block diagram of the sensor layer 200 and the sensor driver 200C according to an embodiment of the present disclosure.

Referring to FIG. 4, the sensor layer 200 may include a plurality of first sensing electrodes 210 and a plurality of second sensing electrodes 220. Each of the second sensing electrodes 220 may cross the first sensing electrodes 210. The sensor layer 200 may further include a plurality of signal lines connected to the first sensing electrodes 210 and the second sensing electrodes 220.

The first sensing electrodes 210 may extend in the first direction DR1, and may be arranged to be spaced apart from each other along the second direction DR2. The second sensing electrodes 220 may extend in the second direction DR2, and may be arranged to be spaced apart from each other along the first direction DR1.

Each of the first sensing electrodes 210 may include a sensing pattern 211 and a connection pattern 212. Two sensing patterns 211 that are adjacent to each other may be electrically connected to each other by two connection patterns 212, but the present disclosure is not limited thereto or thereby. The sensing pattern 211 and the connection patterns 212 may be disposed at (e.g., in or on) different layers from each other.

Each of the second sensing electrodes 220 may include a first portion 221 and a second portion 222. The first portion 221 and the second portion 222 may be integrally provided with each other, and may be disposed at (e.g., in or on) the same layer as each other. As an example, the first portion 221 and the second portion 222 may be disposed at (e.g., in or on) the same layer as that of the sensing pattern 211. Two connection patterns 212 may be insulated from the second portion 222 while crossing the second portion 222.

The sensor controller 200C may receive the control signal I-CS from the main controller 1000C (e.g., refer to FIG. 2). The sensor controller 200C may apply the coordinate signal I-SS to the main controller 1000C.

The sensor controller 200C may be implemented by an integrated circuit (IC) to be mounted (e.g., directly mounted) on a suitable area (e.g., a predetermined area) of the sensor layer 200, or may be electrically connected to the sensor layer 200 after being mounted on a separate printed circuit board in a chip-on-film (COF) method.

The sensor controller 200C may include a sensor control circuit 200C1, a signal generating circuit 200C2, and an input detecting circuit 200C3. The sensor control circuit 200C1 may control an operation of the signal generating circuit 200C2 and the input detecting circuit 200C3 in response to the control signal I-CS.

The signal generating circuit 200C2 may output transmission signals TX to the first sensing electrodes 210 of the sensor layer 200. The input detecting circuit 200C3 may receive sensing signals RX from the sensor layer 200. As an example, the input detecting circuit 200C3 may receive the sensing signals RX from the second sensing electrodes 220. According to an embodiment, the signal generating circuit 200C2 may out the transmission signals TX to the second sensing electrodes 220 of the sensor layer 200, and the input detecting circuit 200C3 may receive the sensing signals RX from the first sensing electrodes 210.

The input detecting circuit 200C3 may convert an analog signal to a digital signal. As an example, the input detecting circuit 200C3 may amplify the analog signal applied thereto, and may filter the amplified signal. In other words, the input detecting circuit 200C3 may convert the filtered signal to the digital signal.

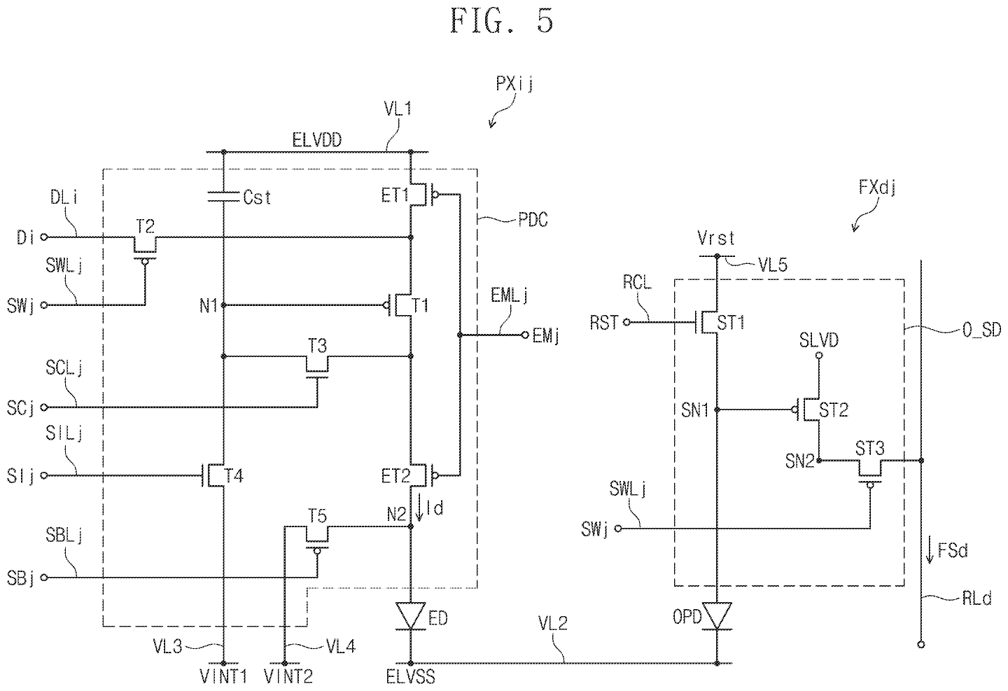

FIG. 5 is an equivalent circuit diagram of a pixel PXij and a sensor FXdj according to an embodiment of the present disclosure.

FIG. 5 shows an equivalent circuit diagram of one pixel PXij from among the pixels PX shown in FIG. 3 as a representative example. Because the pixels PX have the same or substantially the same circuit structure as each other, the pixel PXij will be described in more detail hereinafter with reference to FIG. 5, and redundant description of the other pixels PX may not be repeated. In addition, FIG. 5 shows an equivalent circuit diagram of one sensor FXdj from among the sensors FX shown in FIG. 3 as a representative example. Because the sensors FX have the same or substantially the same circuit structure as each other, the sensor FXdj will be described in more detail hereinafter with reference to FIG. 5, and redundant description of the other sensors FX may not be repeated.

Referring to FIGS. 3 and 5, the pixel PXij may be connected to an i-th data line DLi from among the data lines DL1 to DLm, a j-th initialization scan line SILj from among the initialization scan lines SIL1 to SILn, a j-th compensation scan line SCLj from among the compensation scan lines SCL1 to SCLn, a j-th write scan line SWLj from among the write scan lines SWL1 to SWLn, a j-th black scan line SBLj from among the black scan lines SBL1 to SBLn, and a j-th light emission control line EMLj from among the light emission control lines EML1 to EMLn.

The pixel PXij may include a light emitting element ED and a pixel driving circuit PDC. The light emitting element ED may be a light emitting diode. As an example, the light emitting element ED may be an organic light emitting diode including an organic light emitting layer, but the present disclosure is not limited thereto or thereby.

The pixel driving circuit PDC may include first, second, third, fourth, and fifth transistors T1, T2, T3, T4, and T5, first and second light emission control transistors ET1 and ET2, and one capacitor Cst.

At least one of the first transistor T1, the second transistor T2, the third transistor T3, the fourth transistor T4, the fifth transistor T5, the first light emission control transistor ET1, or the second light emission control transistor ET2 may be a transistor including a low-temperature polycrystalline silicon (LTPS) semiconductor layer. At least one of the first transistor T1, the second transistor T2, the third transistor T3, the fourth transistor T4, the fifth transistor T5, the first light emission control transistor ET1, or the second light emission control transistor ET2 may be a transistor including an oxide semiconductor layer. As an example, each of the third and fourth transistors T3 and T4 may be an oxide semiconductor transistor, and each of the first, second, and fifth transistors T1, T2, and T5 and each of the first and second light emission control transistors ET1 and ET2 may be an LTPS transistor.

In more detail, the first transistor T1, which directly affects a luminance of the display device 1000 (e.g., refer to FIG. 1), may include the semiconductor layer containing polycrystalline silicon having high reliability, and thus, the display device having a high resolution may be implemented. Because an oxide semiconductor has a high carrier mobility and a low leakage current, a voltage drop may not be large even though the driving time is long. In other words, even when the pixels PX are driven at a low frequency, a change in a color of the image due to the voltage drop may not be large, and thus, the pixels PX may be driven at a low frequency. As described above, because the oxide semiconductor has low leakage current, at least one of the third transistor T3 or the fourth transistor T4, which are connected to a third electrode (e.g., a gate electrode) of the first transistor T1, may include the oxide semiconductor. Thus, the leakage current may be prevented or substantially prevented from flowing to the gate electrode of the first transistor T1, and a power consumption may be reduced.

Some of the transistors from among the first to fifth transistors T1 to T5 and the first and second light emission control transistors ET1 and ET2 may be a P-type transistor, and the other transistors may be an N-type transistor. As an example, each of the first, second, and fifth transistors T1, T2, and T5 and the first and second light emission control transistors ET1 and ET2 may be a P-type transistor, and each of the third and fourth transistors T3 and T4 may be an N-type transistor.

The circuit structure of the pixel driving circuit PDC is not limited to the embodiment shown in FIG. 5. The circuit structure of the pixel driving circuit PDC may be variously modified as needed or desired as would be understood by those having ordinary skill in the art. As an example, all of the first to fifth transistors T1 to T5 and the first and second light emission control transistors ET1 and ET2 may be P-type transistors or N-type transistors.

The j-th initialization scan line SILj, the j-th compensation scan line SCLj, the j-th write scan line SWLj, the j-th black scan line SBLj, and the j-th light emission control line EMLj may transmit a j-th initialization scan signal Slj, a j-th compensation scan signal SCj, a j-th write scan signal SWj, a j-th black scan signal SBj, and a j-th light emission control signal EMj, respectively, to the pixel PXij. The i-th data line DLi may transmit an i-th data signal Di to the pixel PXij. The i-th data signal Di may have a voltage level corresponding to the image data RGB (e.g., refer to FIG. 2) input to the display device 1000.

First and second driving voltage lines VL1 and VL2 may transmit the first driving voltage ELVDD and the second driving voltage ELVSS, respectively, to the pixel PXij. In addition, first and second initialization voltage lines VL3 and VL4 may transmit the first initialization voltage VINT1 and the second initialization voltage VINT2, respectively, to the pixel PXij.

The first transistor T1 may be connected between the first driving voltage line VL1 to which the first driving voltage ELVDD is applied, and the light emitting element ED. The first transistor T1 may include a first electrode connected to the first driving voltage line VL1 via the first light emission control transistor ET1, a second electrode connected to the light emitting element ED via the second light emission control transistor ET2, and a third electrode (e.g., a gate electrode) connected to one end of the capacitor Cst (e.g., at a first node N1). The first transistor T1 may receive the i-th data signal Di via the i-th data line DLi according to a switching operation of the second transistor T2, and may supply a driving current Id to the light emitting element ED.

The second transistor T2 may be connected between the data line DLi and the first electrode of the first transistor T1. The second transistor T2 may include a first electrode connected to the data line DLi, a second electrode connected to the first electrode of the first transistor T1, and a third electrode (e.g., a gate electrode) connected to the j-th write scan line SWLj. The second transistor T2 may be turned on in response to the j-th write scan signal SWj applied thereto through the j-th write scan line SWLj, and may transmit the i-th data signal Di provided from the i-th data line DLi to the first electrode of the first transistor T1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the j-th compensation scan line SCLj. The third transistor T3 may be turned on in response to the j-th compensation scan signal SCj applied thereto through the j-th compensation scan line SCLj, and may connect the second electrode and the third electrode of the first transistor T1 to each other, and thus, the first transistor T1 may be connected in a diode configuration (e.g., may be diode-connected).

The fourth transistor T4 may be connected between the first initialization voltage line VL3 to which the first initialization voltage VINT1 is applied, and the first node N1. The fourth transistor T4 may include a first electrode connected to the first initialization voltage line VL3 for transmitting the first initialization voltage VINT1, a second electrode connected to the first node N1, and a third electrode (e.g., a gate electrode) connected to the j-th initialization scan line SILj. The fourth transistor T4 may be turned on in response to the j-th initialization scan signal Slj applied thereto through the j-th initialization scan line SILj. The turned-on fourth transistor T4 may supply the first initialization voltage VINT1 to the first node N1 to initialize an electric potential of the third electrode of the first transistor T1 (e.g., an electric potential of the first node N1).

The first light emission control transistor ET1 may include a first electrode connected to the first driving voltage line VL1, a second electrode connected to the first electrode of the first transistor T1, and a third electrode (e.g., a gate electrode) connected to the j-th light emission control line EMLj.

The second light emission control transistor ET2 may include a first electrode connected to the second electrode of the first transistor T1, a second electrode connected to the light emitting element ED, and a third electrode (e.g., a gate electrode) connected to the j-th light emission control line EMLj.

The first and the second light emission control transistors ET1 and ET2 may be concurrently or substantially simultaneously turned on in response to the j-th light emission control signal EMj applied thereto through the j-th light emission control line EMLj. The first driving voltage ELVDD provided through the turned-on first light emission control transistor ET1 may be compensated for by the first transistor T1 in the diode configuration, and then may be supplied to the light emitting element ED.

The fifth transistor T5 may include a first electrode connected to the second initialization voltage line VL4 to which the second initialization voltage VINT2 is applied, a second electrode connected to the second electrode of the second light emission control transistor ET2, and a third electrode (e.g., a gate electrode) connected to the j-th black scan line SBLj. The second initialization voltage VINT2 may have a voltage level equal to or lower than that of the first initialization voltage VINT1.

As described above, the one end of the capacitor Cst may be connected to the third electrode of the first transistor T1, and the other end of the capacitor Cst may be connected to the first driving voltage line VL1. A cathode of the light emitting element ED may be connected to the second driving voltage line VL2 for transmitting the second driving voltage ELVSS. The second driving voltage ELVSS may have a voltage level lower than that of the first driving voltage ELVDD.

The sensor FXdj may be connected to a d-th read-out line RLd from among the read-out lines RL1 to RLh, the j-th write scan line SWLj (e.g., also referred to as an output control line), and a reset control line RCL.

The sensor FXdj may include an optical sensing element OPD (e.g., also referred to as a sensing element) and a sensor driving circuit O_SD.

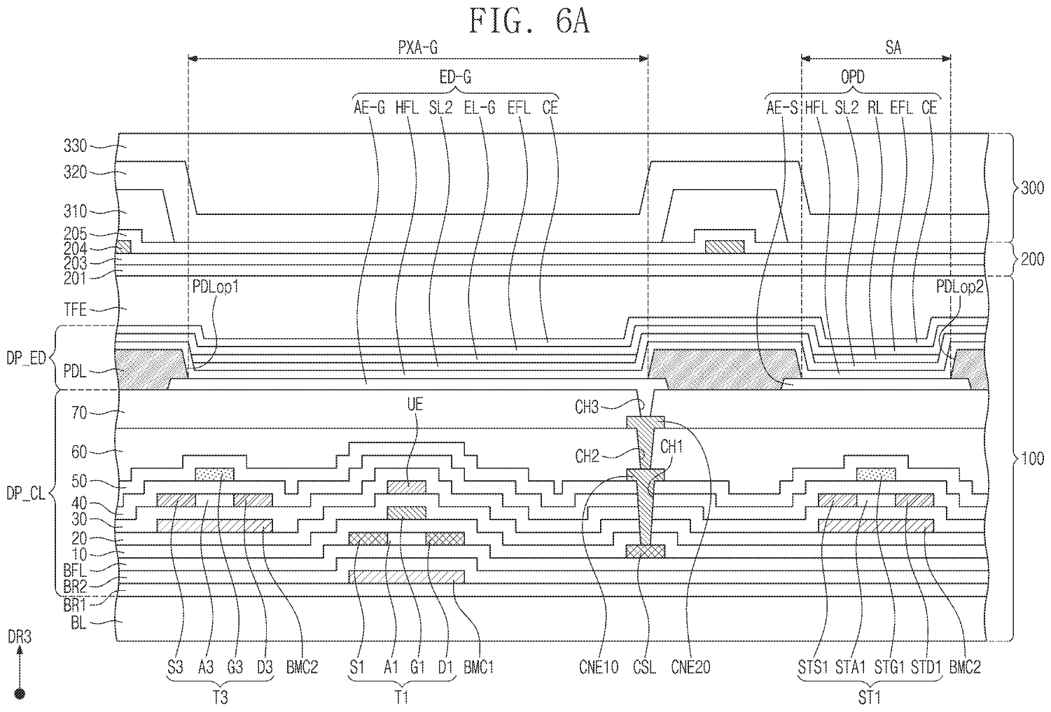

The optical sensing element OPD may be a photodiode, for example, the optical sensing element OPD may be an organic photodiode including an organic material as a photoelectric conversion layer. A first electrode AE-S (e.g., refer to FIG. 6A) of the optical sensing element OPD may be connected to a first sensing node SN1, and a second electrode CE of the optical sensing element OPD may be connected to the second driving voltage line VL2 to which the second driving voltage ELVSS is applied. FIG. 5 shows a structure in which the sensor FXdj includes one optical sensing element OPD as a representative example, but the present disclosure is not limited thereto or thereby. As an example, the sensor FXdj may include z number of optical sensing elements connected in parallel to each other, where “z” may be an integer equal to or greater than 2.

The sensor driving circuit O_SD may include three transistors ST1, ST2, and ST3. The three transistors ST1, ST2, and ST3 may include a reset transistor ST1, an amplification transistor ST2, and an output transistor ST3. At least one of the reset transistor ST1, the amplification transistor ST2, or the output transistor ST3 may be an oxide semiconductor transistor. As an example, the reset transistor ST1 may be the oxide semiconductor transistor, and the amplification transistor ST2 and the output transistor ST3 may be an LTPS transistor. However, the present disclosure is not limited thereto or thereby. According to an embodiment, at least the reset transistor ST1 and the output transistor ST3 may be the oxide semiconductor transistor, and the amplification transistor ST2 may be the LTPS transistor.

In addition, some of the reset transistor ST1, the amplification transistor ST2, and the output transistor ST3 may be a P-type transistor, and the others of the reset transistor ST1, the amplification transistor ST2, and the output transistor ST3 may be an N-type transistor. As an example, each of the amplification transistor ST2 and the output transistor ST3 may be a P-type transistor, and the reset transistor ST1 may be an N-type transistor, but the present disclosure is not limited thereto. According to an embodiment, all of the reset transistor ST1, the amplification transistor ST2, and the output transistor ST3 may be N-type transistors or P-type transistors.

The circuit structure of the sensor driving circuit O_SD is not limited to the embodiment shown in FIG. 5. The circuit structure of the sensor driving circuit O_SD may be variously modified as needed or desired as would be understood by those having ordinary skill in the art.

The reset transistor ST1 may include a first electrode connected to a third initialization voltage line VL5 for receiving the reset voltage Vrst, a second electrode connected to the first sensing node SN1, and a third electrode connected to the reset control line RCL for receiving a reset control signal RST. The reset transistor ST1 may reset an electric potential of the first sensing node SN1 to the reset voltage Vrst in response to the reset control signal RST. The reset control signal RST may be a signal provided through the reset control line RCL.

The amplification transistor ST2 may include a first electrode for receiving a sensing driving voltage SLVD, a second electrode connected to a second sensing node SN2, and a third electrode connected to the first sensing node SN1. The amplification transistor ST2 may be turned on depending on the electric potential of the first sensing node SN1, and may apply the sensing driving voltage SLVD to the second sensing node SN2. As an example, the sensing driving voltage SLVD may be one of the first driving voltage ELVDD, the first initialization voltage VINT1, or the second initialization voltage VINT2. When the sensing driving voltage SLVD is the first driving voltage ELVDD, the first electrode of the amplification transistor ST2 may be electrically connected to the first driving voltage line VL1. When the sensing driving voltage SLVD is the first initialization voltage VINT1, the first electrode of the amplification transistor ST2 may be electrically connected to the first initialization voltage line VL3. When the sensing driving voltage SLVD is the second initialization voltage VINT2, the first electrode of the amplification transistor ST2 may be electrically connected to the second initialization voltage line VL4.

The output transistor ST3 may include a first electrode connected to the second sensing node SN2, a second electrode connected to the d-th read-out line RLd, and a third electrode for receiving the output control signal. The output transistor ST3 may apply a sensing signal FSd to the d-th read-out line RLd in response to the output control signal. The output control signal may be the j-th write scan signal SWj (e.g., also referred to as a j-th output control signal) provided through the j-th write scan line SWLj. In other words, the output transistor ST3 may receive the j-th write scan signal SWj provided through the j-th write scan line SWLj as the output control signal.

A reset period may be defined as an activation period of the reset control line RCL (e.g., a high level period). When the reset control signal RST having a high level is provided through the reset control line RCL, the reset transistor ST1 may be turned on. As another example, when the reset transistor ST1 is the PMOS transistor, the reset control signal RST having a low level may be applied to the reset control line RCL during the reset period. During the reset period, the first sensing node SN1 may be reset to an electric potential corresponding to the reset voltage Vrst. As an example, the reset voltage Vrst may have a voltage level lower than that of the second driving voltage ELVSS.

The optical sensing element OPD of the sensor FXdj may be exposed to light emitted from the light emitting element ED during a light emitting period of the light emitting element ED. A voltage of the first sensing node SN1 may be maintained or substantially maintained at the reset voltage Vrst in the reset period, and the voltage of the first sensing node SN1 may be gradually shifted to the second driving voltage ELVSS as the optical sensing element OPD is exposed to the light. The amplification transistor ST2 may be a source follower amplifier that generates a source-drain current that is proportional to an amount of electric charges of the first sensing node SN1 input to the gate electrode.

In an output period, the j-th write scan signal SWj having the low level may be applied to the output transistor ST3 via the j-th write scan line SWLj. When the output transistor ST3 is turned on in response to the j-th write scan signal SWj having the low level, the sensing signal FSd corresponding to a current flowing through the amplification transistor ST2 may be output to the read-out line RLd.

FIG. 6A is a cross-sectional view of the display device according to an embodiment of the present disclosure. FIG. 6B is a cross-sectional view of a portion of the display layer according to an embodiment of the present disclosure.

Referring to FIGS. 6A and 6B, the display layer 100 may include a base layer BL, a circuit layer DP_CL, an element layer DP_ED, and an encapsulation layer TFE. The circuit layer DP_CL, the element layer DP_ED, and the encapsulation layer TFE may be disposed on the base layer BL.

At least one inorganic layer may be disposed on an upper surface of the base layer BL. The inorganic layer may include at least one of aluminum oxide, titanium oxide, silicon oxide, silicon oxynitride, zirconium oxide, or hafnium oxide. The inorganic layer may be formed in multiple layers. The inorganic layers may form barrier layers BR1 and BR2, and/or a buffer layer BFL described in more detail below. According to an embodiment, the barrier layers BR1 and BR2 and the buffer layer BFL may be selectively disposed on the base layer BL as needed or desired.

The barrier layers BR1 and BR2 may prevent or substantially prevent a foreign substance from entering from the outside. The barrier layers BR1 and BR2 may include a silicon oxide layer and a silicon nitride layer. Each of the silicon oxide layer and the silicon nitride layer may be provided in a plurality, and the silicon oxide layers may be alternately stacked with the silicon nitride layers.

The barrier layers BR1 and BR2 may include a first barrier layer BR1 and a second barrier layer BR2. A first rear surface metal layer BMC1 may be disposed between the first barrier layer BR1 and the second barrier layer BR2. According to an embodiment, the first rear surface metal layer BMC1 may be omitted as needed or desired.

The buffer layer BFL may be disposed on the barrier layers BR1 and BR2. The buffer layer BFL may increase an adhesion between the base layer BL and a semiconductor pattern, or between the base layer BL and a conductive pattern. The buffer layer BFL may include a silicon oxide layer and a silicon nitride layer. The silicon oxide layer and the silicon nitride layer may be alternately stacked one on another.

A first semiconductor pattern may be disposed on the buffer layer BFL. The first semiconductor pattern may include a silicon semiconductor. As an example, the silicon semiconductor may include amorphous silicon, polycrystalline silicon, or the like. As an example, the first semiconductor pattern may include low temperature polysilicon.

FIG. 6A shows a portion of the first semiconductor pattern disposed on the buffer layer BFL, and the first semiconductor pattern may be further disposed in other areas. The first semiconductor pattern may be arranged with a suitable rule (e.g., a specific or predetermined rule) over the pixels PX. The first semiconductor pattern may have different electrical properties depending on whether it is doped or not, or whether it is doped with an N-type dopant or a P-type dopant. The first semiconductor pattern may include a first region with a relatively high conductivity, and a second region with a relatively low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region, or a region doped with a relatively lower concentration compared with that of the first region.

The first region may have the conductivity greater than that of the second region, and may serve or substantially serve as electrodes or signal lines of a transistor. The second region may correspond to or substantially correspond to an active area (or a channel) of the transistor. In other words, a portion of the semiconductor pattern may be the active area of the transistor, another portion of the semiconductor pattern may be a source or a drain of the transistor, and another portion of the semiconductor pattern may be a connection electrode or a connection signal line.

A first electrode S1, an active area A1, and a second electrode D1 of the first transistor T1 may be formed from the first semiconductor pattern. The first electrode S1 and the second electrode D1 of the first transistor T1 may extend in opposite directions to each other from the active area A1.

FIG. 6A shows a portion of a connection signal line CSL formed from the first semiconductor pattern. The connection signal line CSL may be connected to the second electrode of the fifth transistor T5 (e.g., refer to FIG. 5) when viewed in the plane (e.g., in a plan view).

A first insulating layer 10 may be disposed on the buffer layer BFL. The first insulating layer 10 may commonly overlap with the pixels PX, and may cover the first semiconductor pattern. The first insulating layer 10 may be an inorganic layer and/or an organic layer, and may have a single-layer or multi-layered structure. The first insulating layer 10 may include at least one of aluminum oxide, titanium oxide, silicon oxide, silicon nitride, silicon oxynitride, zirconium oxide, or hafnium oxide. In an embodiment, the first insulating layer 10 may have a single-layer structure of a silicon oxide layer. Not only the first insulating layer 10, but also an insulating layer of the circuit layer DP_CL described in more detail below may be an inorganic layer and/or an organic layer, and may have a single-layer or multi-layered structure. The inorganic layer may include at least one of the above-mentioned materials, but it is not limited thereto or thereby.

A third electrode G1 of the first transistor T1 may be disposed on the first insulating layer 10. The third electrode G1 may be a portion of a metal pattern. The third electrode G1 of the first transistor T1 may overlap with the active area A1 of the first transistor T1. The third electrode G1 of the first transistor T1 may be used as a mask in a process of doping the first semiconductor pattern. The third electrode G1 of the first transistor T1 may include titanium (Ti), silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), indium tin oxide (ITO), indium zinc oxide (IZO), or the like, but it is not particularly limited thereto.

A second insulating layer 20 may be disposed on the first insulating layer 10, and may cover the third electrode G1 of the first transistor T1. The second insulating layer 20 may be an inorganic layer and/or an organic layer, and may have a single-layer or multi-layered structure. The second insulating layer 20 may include at least one of silicon oxide, silicon nitride, or silicon oxynitride. In an embodiment, the second insulating layer 20 may have a multi-layered structure of a silicon oxide layer and a silicon nitride layer.

An upper electrode UE and a second rear surface metal layer BMC2 may be disposed on the second insulating layer 20. The upper electrode UE may overlap with the third electrode G1. The upper electrode UE may be a portion of a metal pattern. A portion of the third electrode G1 and the upper electrode UE overlapping with each other may define the capacitor Cst (e.g., refer to FIG. 5). According to an embodiment, the second insulating layer 20 may be replaced with an insulating pattern. In this case, the upper electrode UE may be disposed on the insulating pattern, and may serve as a mask in the process of forming the insulating pattern from the second insulating layer 20.

The second rear surface metal layer BMC2 may be disposed to correspond to a lower portion of an oxide thin film transistor (e.g., a lower portion of the third transistor T3). The second rear surface metal layer BMC2 may receive a constant or substantially constant voltage or a signal.

A third insulating layer 30 may be disposed on the second insulating layer 20 to cover the upper electrode UE and the second rear surface metal layer BMC2. The third insulating layer 30 may have a single-layer or multi-layered structure. As an example, the third insulating layer 30 may have a multi-layered structure of a silicon oxide layer and a silicon nitride layer.

A second semiconductor pattern may be disposed on the third insulating layer 30. The second semiconductor pattern may include an oxide semiconductor. The oxide semiconductor may include a plurality of areas distinguished from each other depending on whether a metal oxide is reduced or not. An area (hereinafter, referred to as a reduced area) where the metal oxide is reduced may have a conductivity higher than that of an area (hereinafter, referred to as a non-reduced area) where the metal oxide is not reduced. The reduced area may act or substantially act as the source/drain of the transistor or the signal line. The non-reduced area may correspond to or substantially correspond to the active area (or referred to as a semiconductor area or a channel) of the transistor. In other words, a portion of the second semiconductor pattern may be the active area of the transistor, another portion of the second semiconductor pattern may be the source or the drain of the transistor, and another portion may be a signal transmission area.

A first electrode S3, an active area A3, and a second electrode D3 of the third transistor T3 may be formed from the second semiconductor pattern. The first electrode S3 and the second electrode D3 may include the metal reduced from the metal oxide semiconductor. The first electrode S3 and the second electrode D3 may extend in opposite directions from each other from the active area A3.

A fourth insulating layer 40 may be disposed on the third insulating layer 30. The fourth insulating layer 40 may commonly overlap with the pixels PX, and may cover the second semiconductor pattern. The fourth insulating layer 40 may include at least one of aluminum oxide, titanium oxide, silicon oxide, silicon nitride, silicon oxynitride, zirconium oxide, or hafnium oxide.

A third electrode G3 of the third transistor T3 may be disposed on the fourth insulating layer 40. The third electrode G3 may be a portion of a metal pattern. The third electrode G3 of the third transistor T3 may overlap with the active area A3 of the third transistor T3. The third electrode G3 may serve as a mask in a process of reducing the second semiconductor pattern. According to an embodiment, the fourth insulating layer 40 may be replaced with an insulating pattern.

A fifth insulating layer 50 may be disposed on the fourth insulating layer 40 to cover the third electrode G3. The fifth insulating layer 50 may be an inorganic layer.

A first connection electrode CNE10 may be disposed on the fifth insulating layer 50. The first connection electrode CNE10 may be connected to the connection signal line CSL via a first contact hole CH1 defined through (e.g., penetrating) the first to fifth insulating layers 10 to 50.

A sixth insulating layer 60 may be disposed on the fifth insulating layer 50. The sixth insulating layer 60 may be an organic layer. The organic layer may include a general-purpose polymer, such as benzocyclobutene (BCB), polyimide, hexamethyldisiloxane (HMDSO), polymethylmethacrylate (PMMA), or polystyrene (PS), a polymer derivative having a phenolic group, an acrylic-based polymer, an imide-based polymer, an aryl ether-based polymer, an amide-based polymer, a fluorine-based polymer, a p-xylene-based polymer, a vinyl alcohol-based polymer, or a suitable blend thereof, however, the present disclosure is not limited thereto or thereby.

A second connection electrode CNE20 may be disposed on the sixth insulating layer 60. The second connection electrode CNE20 may be connected to the first connection electrode CNE10 via a second contact hole CH2 defined through (e.g., penetrating) the sixth insulating layer 60. A seventh insulating layer 70 may be disposed on the sixth insulating layer 60, and may cover the second connection electrode CNE20. The seventh insulating layer 70 may be an organic layer.

The circuit layer DP_CL may further include the sensor driving circuit O_SD (e.g., refer to FIG. 5). For convenience of illustration, the reset transistor ST1 of the sensor driving circuit O_SD is shown in FIG. 6A. A first electrode STS1, an active area STA1, and a second electrode STD1 of the reset transistor ST1 may be formed from the second semiconductor pattern. The first electrode STS1 and the second electrode STD1 may include the metal reduced from the metal oxide semiconductor. The fourth insulating layer 40 may be disposed to cover the first electrode STS1, the active area STA1, and the second electrode STD1 of the reset transistor ST1. A third electrode STG1 of the reset transistor ST1 may be disposed on the fourth insulating layer 40. In an embodiment, the third electrode STG1 may be a portion of the metal pattern. The third electrode STG1 of the reset transistor ST1 may overlap with the active area STA1 of the reset transistor ST1.

As an example, the reset transistor ST1 and the third transistor T3 may be disposed at (e.g., in or on) the same layer as each other. In other words, the first electrode STS1, the active area STA1, and the second electrode STD1 of the reset transistor ST1 may be formed through the same processes as those of the first electrode S3, the active area A3, and the second electrode D3 of the third transistor T3. The third electrode STG1 of the reset transistor ST1 may be concurrently or substantially simultaneously formed with the third electrode G3 of the third transistor T3 through the same processes. The first and second electrodes of the amplification transistor ST2 and the output transistor ST3 of the sensor driving circuit O_SD may be formed through the same processes as those of the first electrode S1 and the second electrode D1 of the first transistor T1. Because the reset transistor ST1 and the third transistor T3 are formed at (e.g., in or on) the same layer as each other through the same processes as each other, no additional processes are used to form the reset transistor ST1. Thus, a process efficiency may be improved, and manufacturing costs may be reduced.

Referring to FIGS. 6A and 6B, the element layer DP_ED may be disposed on the circuit layer DP_CL. The element layer DP_ED may include light emitting elements ED-R, ED-G, and ED-B, and the optical sensing elements OPD. The light emitting elements ED-R, ED-G, and ED-B may include a first light emitting element ED-R, a second light emitting element ED-G, and a third light emitting element ED-B. FIG. 6A shows one light emitting element ED-G and one optical sensing element OPD as a representative example.

A first light emitting area PXA-R may be defined to correspond to the first light emitting element ED-R. A second light emitting area PXA-G may be defined to correspond to the second light emitting element ED-G. A third light emitting area PXA-B may be defined to correspond to the third light emitting element ED-B. A sensing area SA may be defined to correspond to the optical sensing element OPD. The first, second, and third light emitting areas PXA-R, PXA-G, and PXA-B and the sensing area SA may be defined by a pixel definition layer PDL described in more detail below.

The light emitting elements ED-R, ED-G, and ED-B may include first electrodes AE-R, AE-G, and AE-B, a first functional layer HFL, light emitting layers EL-R, EL-G, and EL-B, a second functional layer EFL, and a second electrode CE. The optical sensing element OPD may include a first electrode AE-S, the first functional layer HFL, a photoelectric conversion layer RL, the second functional layer EFL, and the second electrode CE. The first functional layer HFL, the second functional layer EFL, and the second electrode CE may be commonly provided to the pixels PX (e.g., refer to FIG. 3) and the sensors FX.

Referring to FIG. 6A, the first electrode AE-G of the second light emitting element ED-G and the first electrode AE-S of the optical sensing element OPD may be disposed on the seventh insulating layer 70. The first electrode AE-G of the second light emitting element ED-G may be connected to the second connection electrode CNE20 via a third contact hole CH3 defined through (e.g., penetrating) the seventh insulating layer 70.

The light emitting elements ED-R, ED-G, and ED-B may further include first, second, and third auxiliary layers SL1, SL2, and SL3. According to an embodiment, at least a portion of the first, second, and third auxiliary layers SL1, SL2, and SL3 may be omitted as needed or desired.

The auxiliary layers SL1, SL2, and SL3 may include a first auxiliary layer SL1 disposed in the first light emitting area PXA-R, a second auxiliary layer SL2 commonly disposed in the second light emitting area PXA-G and the sensing area SA, and a third auxiliary layer SL3 disposed in the third light emitting area PXA-B. The first auxiliary layer SL1 may be disposed between the first functional layer HFL and the first light emitting layer EL-R. The second auxiliary layer SL2 may be disposed between the first functional layer HFL and the second light emitting layer EL-G, and between the first functional layer HFL and the photoelectric conversion layer RL. The third auxiliary layer SL3 may be disposed between the first functional layer HFL and the third light emitting layer EL-B.

The first, second, and third auxiliary layers SL1, SL2, and SL3 may be provided to control a resonant distance. Accordingly, the first, second, and third auxiliary layers SL1, SL2, and SL3 may have different thicknesses (e.g., in the third direction DR3) from each other. As shown in FIG. 6B, the first auxiliary layer SL1 may have the greatest thickness, and the third auxiliary layer SL3 may have the smallest thickness. However, the present disclosure is not limited thereto or thereby.

According to an embodiment, the second auxiliary layer SL2 of the optical sensing element OPD and the second auxiliary layer SL2 disposed in the second light emitting area PXA-G may be concurrently or substantially simultaneously formed with each other through the same process. As an example, the second auxiliary layer SL2 may be formed using one fine metal mask. Accordingly, a manufacturing time used to manufacture the display device 1000 (e.g., refer to FIG. 1) may be reduced.

The pixel definition layer PDL may be disposed on the seventh insulating layer 70, and may cover a portion of each of the first electrodes AE-R, AE-G, AE-B, and AE-S. The pixel definition layer PDL may be provided with openings PDLop1 and PDLop2 defined (e.g., penetrating) therethrough. The light emitting areas PXA-R, PXA-G, and PXA-B and the sensing areas SA may be defined by the openings PDLop1 and PDLop2.

FIG. 6A shows the second light emitting area PXA-G from among the light emitting areas PXA-R, PXA-G, and PXA-B, and one sensing area SA from among the sensing areas SA as a representative example. As an example, the second light emitting area PXA-G may be defined by a first opening PDLop1, and the sensing area SA may be defined by a second opening PDLop2. At least a portion of the first electrode AE-G of the second light emitting element ED-G may be exposed through the first opening PDLop1, and at least a portion of the first electrode AE-S of the optical sensing element OPD may be exposed through the second opening PDLop2.

According to an embodiment, the pixel definition layer PDL may further include a black material. The pixel definition layer PDL may include a black organic dye/pigment, such as carbon black or aniline black. The pixel definition layer PDL may be formed by mixing a blue organic material with a black organic material. The pixel definition layer PDL may further include a liquid-repellent organic material.

The second light emitting layer EL-G of the second light emitting element ED-G may be disposed in an area corresponding to the first opening PDLop1. The second light emitting layer EL-G may emit a desired colored light (e.g., a certain or predetermined colored light). In the present embodiment, the light emitting layers EL-R, EL-G, and EL-B are illustrated as being patterned, but on another embodiment, one light emitting layer may be commonly disposed over the light emitting areas. In this case, the one light emitting layer may generate white light or blue light. In addition, the light emitting layer may have a multi-layered structure, which is referred to as a tandem structure.

Each of the light emitting layers EL-R, EL-G, and EL-B may include a low molecular organic material or a high molecular organic material as the light emitting material. According to an embodiment, each of the light emitting layers EL-R, EL-G, and EL-B may include a quantum dot as the light emitting material. A core of the quantum dot may be selected from among a group II-VI compound, a group III-V compound, a group IV-VI compound, a group IV element, a group IV compound, or suitable combinations thereof.

The photoelectric conversion layer RL may be disposed in an area corresponding to the second opening PDLop2. The photoelectric conversion layer RL may include an organic photo-sensing material. The second electrode CE may be disposed on the photoelectric conversion layer RL. Each of the first electrode AE-S and the second electrode CE may receive an electrical signal. The first electrode AE-S and the second electrode CE may receive different signals from each other. Accordingly, a desired electric field (e.g., a predetermined electric field) may be formed between the first electrode AE-S and the second electrode CE. The photoelectric conversion layer RL may generate an electrical signal corresponding to light incident into a sensor.

The electric field formed between the first electrode AE-S and the second electrode CE may be changed by electric charges generated in the photoelectric conversion layer RL. An amount of the electric charges generated in the photoelectric conversion layer RL may vary depending on whether or not light is incident to the optical sensing element OPD, an amount of the light incident to the optical sensing element OPD, and an intensity of the light incident to the optical sensing element OPD. Accordingly, the electric field formed between the first electrode AE-S and the second electrode CE may be changed. The optical sensing element OPD may obtain fingerprint information of the user based on the change in the electric field between the first electrode AE-S and the second electrode CE.

In some embodiments, the element layer DP_ED may further include a capping layer disposed on the second electrode CE. The capping layer may improve light emission efficiency by a principle of constructive interference. The capping layer may include a suitable material having a refractive index equal to or greater than about 1.6 with respect to light having a wavelength of about 589 nm. The capping layer may be an organic capping layer including an organic material, an inorganic capping layer including an inorganic material, or a composite capping layer including the organic material and the inorganic material. For example, the capping layer may include carbocyclic compounds, heterocyclic compounds, amine group-containing compounds, porphine derivatives, phthalocyanine derivatives, naphthalocyanine derivatives, alkali metal complexes, alkaline earth metal complexes, or any suitable combination thereof. The carbocyclic compounds, the heterocyclic compounds, and the amine group-containing compounds may optionally be substituted with substituents including O, N, S, Se, Si, F, Cl, Br, I, or any suitable combination thereof.

The encapsulation layer TFE may be disposed on the element layer DP_ED. The encapsulation layer TFE may include at least an inorganic layer or an organic layer. According to an embodiment, the encapsulation layer TFE may include two inorganic layers, and an organic layer disposed between the inorganic layers. According to an embodiment, a thin film encapsulation layer may include a plurality of inorganic layers, and a plurality of organic layers alternately stacked with the inorganic layers.

An encapsulation inorganic layer may protect the second light emitting element ED-G and the optical sensing element OPD from moisture and oxygen, and an encapsulation organic layer may protect the second light emitting element ED-G and the optical sensing element OPD from a foreign substance, such as dust particles. The encapsulation inorganic layer may include a silicon nitride layer, a silicon oxynitride layer, a silicon oxide layer, a titanium oxide layer, or an aluminum oxide layer, but is not particularly limited thereto. The encapsulation organic layer may include an acrylic-based organic layer, but is not particularly limited thereto.

The display device 1000 (e.g., refer to FIG. 1) may further include the sensor layer 200 and an anti-reflective layer 300.

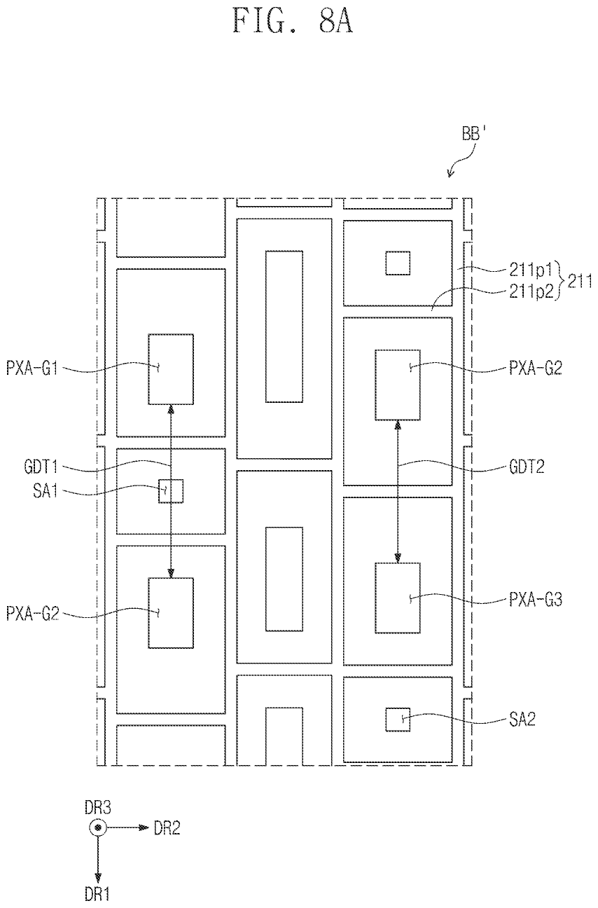

The sensor layer 200 may be disposed on the display layer 100. The sensor layer 200 may sense an external input applied from the outside. The external input may be a user input. The user input may include a variety of suitable external inputs, such as a part of user's body, light, heat, pen, and/or pressure. The sensor layer 200 may be referred to as a sensor, an input sensing layer, or an input sensing panel. The sensor layer 200 may include a sensor base layer 201, a first sensor conductive layer 202 (e.g., refer to FIG. 9A), a sensor insulating layer 203, a second sensor conductive layer 204, and a sensor cover layer 205.

The sensor base layer 201 may be disposed directly on the display layer 100. The sensor base layer 201 may be an inorganic layer including at least one of silicon nitride, silicon oxynitride, or silicon oxide. According to an embodiment, the sensor base layer 201 may be an organic layer including an epoxy resin, an acrylic resin, or an imide-based resin. The sensor base layer 201 may have a single-layer structure, or a multi-layered structure of a plurality of layers stacked in the third direction DR3.

Each of the first sensor conductive layer 202 and the second sensor conductive layer 204 may have a single-layer structure, or a multi-layered structure of a plurality of layers stacked in the third direction DR3.

The conductive layer having the single-layer structure may include a metal layer or a transparent conductive layer. The metal layer may include molybdenum, silver, titanium, copper, aluminum, or suitable alloys thereof. The transparent conductive layer may include a transparent conductive oxide, such as indium tin oxide (ITO), indium zinc oxide (IZO), zinc oxide (ZnO), indium zinc tin oxide (ITZO), or the like. In addition, the transparent conductive layer may include a conductive polymer, such as PEDOT, a metal nanowire, graphene, or the like.

The conductive layer having the multi-layered structure may include a plurality of metal layers. The metal layers may have a three-layered structure of titanium/aluminum/titanium. The conductive layer having the multi-layered structure may include at least one metal layer and at least one transparent conductive layer.

The sensor insulating layer 203 may be disposed between the first sensor conductive layer 202 and the second sensor conductive layer 204. The sensor insulating layer 203 may include an inorganic layer. The inorganic layer may include at least one of aluminum oxide, titanium oxide, silicon oxide, silicon nitride, silicon oxynitride, zirconium oxide, or hafnium oxide.

According to an embodiment, the sensor insulating layer 203 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

The sensor cover layer 205 may be disposed on the sensor insulating layer 203, and may cover the second sensor conductive layer 204. The second sensor conductive layer 204 may include a conductive pattern. The sensor cover layer 205 may cover the conductive pattern, and may reduce or prevent occurrence of damages in the conductive pattern in a subsequent process. The sensor cover layer 205 may include an inorganic material. As an example, the sensor cover layer 205 may include silicon nitride, but is not limited thereto or thereby. According to an embodiment, the sensor cover layer 205 may be omitted as needed or desired.

The anti-reflective layer 300 may be disposed on the sensor layer 200. The anti-reflective layer 300 may include a division layer 310, a plurality of color filters 320, and a planarization layer 330.

The division layer 310 may be disposed to overlap with the conductive pattern of the second sensor conductive layer 204. The sensor cover layer 205 may be disposed between the division layer 310 and the second sensor conductive layer 204. The division layer 310 may prevent or substantially prevent external light from being reflected by the second sensor conductive layer 204. Materials for the division layer 310 are not particularly limited, as long as the materials absorb light. The division layer 310 may have a black color, and may include a black coloring agent. The black coloring agent may include a black dye or a black pigment. The black coloring agent may include a metal material, such as carbon black, chromium, or an oxide thereof.

The division layer 310 may be provided with a plurality of division openings defined therethrough. The division openings may overlap with the light emitting layers EL-R, EL-G, and EL-B and the photoelectric conversion layer RL, respectively. The color filters 320 may be disposed to correspond to the division openings. The color filters 320 may transmit light provided from the light emitting layers EL-R, EL-G, and EL-B overlapping with the color filters 320. According to an embodiment, the light may be provided to the photoelectric conversion layer RL after passing through the color filter 320.

FIG. 6A shows a structure in which one color filter 320 is commonly provided to the second light emitting layer EL-G and the photoelectric conversion layer RL as a representative example. However, the present disclosure is not particularly limited thereto. As an example, another color filter other than a green color filter may be disposed on the photoelectric conversion layer RL. According to an embodiment, the color filter 320 may not be disposed on the photoelectric conversion layer RL.

The planarization layer 330 may cover the division layer 310 and the color filters 320. The planarization layer 330 may include an organic material, and may provide a flat or substantially flat surface on the upper surface thereof. According to an embodiment, the planarization layer 330 may be omitted as needed or desired.

According to an embodiment, the anti-reflective layer 300 may include a reflection adjusting layer instead of the color filters 320. As an example, the color filters 320 may be omitted from the display device illustrated in FIG. 6A, and the reflection adjusting layer may be provided in place of the color filters 320. The reflection adjusting layer may selectively absorb light in some bands from among the light reflected inside the display panel and/or the electronic device, or light incident from outside the display panel and/or the electronic device.

As an example, the reflection adjusting layer may absorb light in a first wavelength region from about 490 nm to about 505 nm, and light in a second wavelength region from about 585 nm to about 600 nm, and thus, the light transmittance in the first wavelength region and the second wavelength region may be equal to or smaller than about 40%. The reflection adjusting layer may absorb light of wavelengths outside a wavelength range of the red, green, and blue lights emitted from the light emitting layers EL-R, EL-G, and EL-B. As described above, because the reflection adjusting layer absorbs the light of the wavelengths that are not included in the wavelength range of the red, green, and blue light emitted from the light emitting layers EL-R, EL-G, and EL-B, the luminance of the display panel and/or the electronic device may be prevented or substantially prevented from being reduced. In addition, deterioration of the light emission efficiency of the display panel and/or the electronic device may be prevented or substantially prevented, and visibility of the display panel and/or the electronic device may be improved.

The reflection adjusting layer may be provided with an organic material layer containing dyes, pigments, or a suitable combination thereof. The reflection adjusting layer may include a tetraazaporphyrin-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, and/or various suitable combinations thereof.

According to an embodiment, the reflection adjusting layer may have a transmittance of about 64% to about 72%. The transmittance of the reflection adjusting layer may be controlled according to a content of the pigment and/or dye included in the reflection adjusting layer.

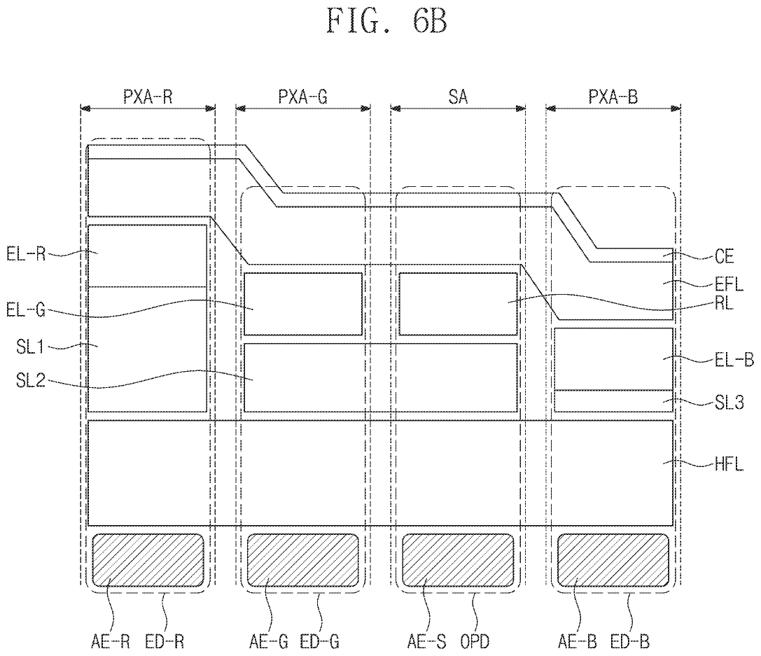

FIG. 7 is an enlarged plan view of the area AA′ of FIG. 4.

Referring to FIGS. 6A and 7, each of the first, second, and third light emitting areas PXA-R, PXA-G, and PXA-B and the sensing area SA may have a quadrangular shape defined by corresponding first sides S-DR1 extending in the first direction DR1, and corresponding second sides S-DR2 extending in the second direction DR2. The first light emitting area PXA-R may be a red light emitting area, the second light emitting area PXA-G may be a green light emitting area, and the third light emitting area PXA-B may be a blue light emitting area.

The first, second, and third light emitting areas PXA-R, PXA-G, and PXA-B and the sensing area SA may have different sizes from each other. As an example, the third light emitting area PXA-B may have the longest width in the first direction DR1, and the sensing area SA may have the smallest width in the first direction DR1.

The first light emitting areas PXA-R and the third light emitting areas PXA-B may be arranged alternately and repeatedly one by one along the first direction DR1. The second light emitting areas PXA-G may be consecutively arranged along the first direction DR1. One third light emitting area PXA-B, one second light emitting area PXA-G, one first light emitting area PXA-R, and one second light emitting area PXA-G may be sequentially and repeatedly arranged along the second direction DR2.

The second light emitting areas PXA-G may include a first-second light emitting area PXA-G1, a second-second light emitting area PXA-G2, and a third-second light emitting area PXA-G3, which are consecutively and repeatedly arranged along the first direction DR1. A first sensing area SA1 from among the sensing areas SA may be disposed between the first-second light emitting area PXA-G1 and the second-second light emitting area PXA-G2. A second sensing area SA2 from among the sensing areas SA may be disposed in an area spaced apart from the second-second light emitting area PXA-G2, with the third-second light emitting area PXA-G3 interposed therebetween. The first sensing area SA1 and the second sensing area SA2 may be closest to each other in the first direction DR1 from among the sensing areas SA.

FIG. 7 shows the first auxiliary layer SL1, the second auxiliary layer SL2, and the third auxiliary layer SL3, which are described above with reference to FIGS. 6A and 6B, as a representative example. The first, second, and third auxiliary layers SL1, SL2, and SL3 may be disposed in all of the corresponding ones of the first, second, and third light emitting areas PXA-R, PXA-G, and PXA-B and the sensing area SA, but FIG. 7 shows only one first auxiliary layer SL1, one second auxiliary layer SL2, and one third auxiliary layer SL3 as a representative example.

The second auxiliary layer SL2 may be commonly disposed in the first-second light emitting area PXA-G1, the first sensing area SA1, and the second-second light emitting area PXA-G2. Accordingly, the second auxiliary layer SL2 may be commonly disposed between the first functional layer HFL and a light emitting layer of the first-second light emitting area PXA-G1, between the first functional layer HFL and a light emitting layer of the second-second light emitting area PXA-G2, and between the first functional layer HFL and a photoelectric conversion layer of the first sensing area SA1.

The sensing pattern 211 may be disposed between the first, second, and third light emitting areas PXA-R, PXA-G, and PXA-B and the sensing area SA. The sensing pattern 211 may have a mesh structure, and may have a shape that extends and does not overlap with the first, second, and third light emitting areas PXA-R, PXA-G, and PXA-B and the sensing area SA. As an example, the sensing pattern 211 may include a first-first line 211p1 extending in the first direction DR1, and a second-first line 211p2 extending in the second direction DR2 crossing (e.g., intersecting) the first direction DR1. An angle between the first direction DR1 and the second direction DR2 may be about 90 degrees, and the first direction DR1 may be perpendicular to or substantially perpendicular to the second direction DR2. The first-first line 211p1 may be electrically connected to the second-first line 211p2. The sensing pattern 211 may be included in the second conductive layer 204 (e.g., refer to FIG. 6A), but is not particularly limited thereto. According to an embodiment, the sensing pattern 211 may be disposed between the sensor base layer 201 and the sensor insulating layer 203.

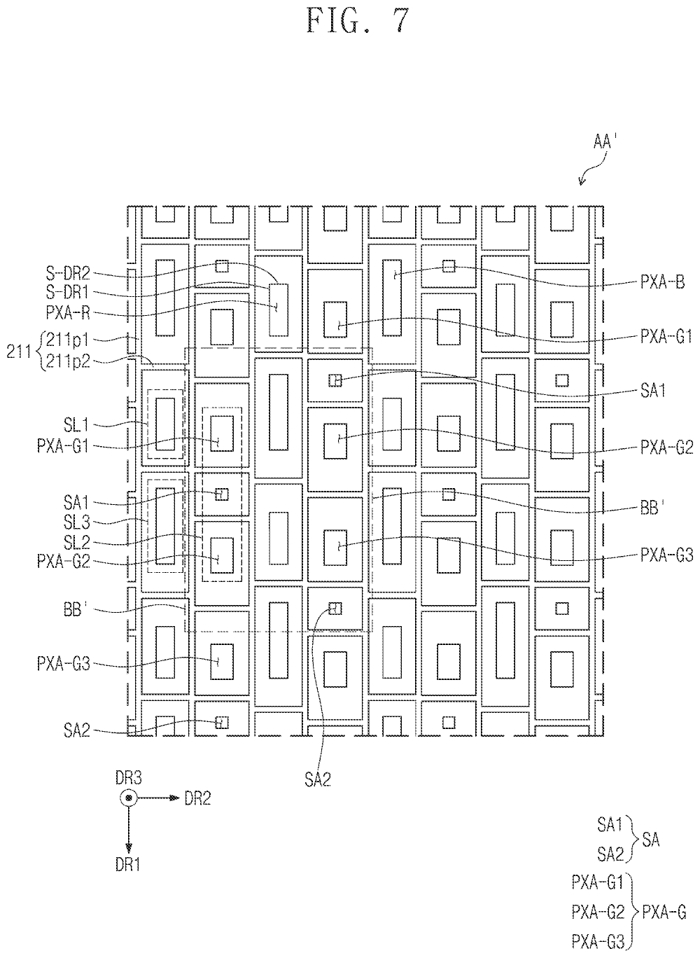

FIG. 8A is an enlarged plan view of the area BB′ of FIG. 7.

Referring to FIGS. 7 and 8A, the second light emitting areas PXA-G1, PXA-G2, and PXA-G3 may be irregularly arranged. As an example, a first distance GDT1 between the first-second light emitting area PXA-G1 and the second-second light emitting area PXA-G2 may be different from a second distance GDT2 between the second-second light emitting area PXA-G2 and the third-second light emitting area PXA-G3.

As an example, the first sensing area SA1 may be disposed between the first-second light emitting area PXA-G1 and the second-second light emitting area PXA-G2, and a sensing area may not be disposed between the second-second light emitting area PXA-G2 and the third-second light emitting area PXA-G3. In this case, the first distance GDT1 may be greater than the second distance GDT2.

According to an embodiment, the first distance GDT1 may be adjusted according to a size of the first sensing area SA1. As an example, as the size of the first sensing area SA1 increases, the first distance GDT1 may increase.

FIG. 8B is an enlarged plan view of the area BB′ of FIG. 7 according to an embodiment of the present disclosure.

Referring to FIGS. 7 and 8B, the second light emitting areas PXA-G1, PXA-G2, and PXA-G3 may be regularly arranged. As an example, a first distance GDT1a between the first-second light emitting area PXA-G1 and the second-second light emitting area PXA-G2 may be the same or substantially the same as a second distance GDT2 between the second-second light emitting area PXA-G2 and the third-second light emitting area PXA-G3.

FIG. 9A is an enlarged plan view of the area CC′ of FIG. 4.

Referring to FIGS. 6A and 9A, the first sensor conductive layer 202 is disposed between the sensor base layer 201 and the sensor insulating layer 203. The first sensor conductive layer 202 may include the connection patterns 212 and dummy patterns DMP.

The connection patterns 212 may be provided to electrically connect the sensing patterns 211 (e.g., refer to FIG. 9B) that are spaced apart from each other to each other. Each of the connection patterns 212 may include a first connection line 212p1 extending in the first direction DR1, and a second connection line 212p2 extending in the second direction DR2.

The dummy patterns DMP may be electrically insulated from the connection patterns 212. As an example, the dummy patterns DMP may be electrically floated. FIG. 9A shows four dummy patterns DMP that are adjacent to two connection patterns 212 as a representative example, but the number of the dummy patterns DMP is not limited thereto or thereby. According to an embodiment, the dummy patterns DMP may be omitted as needed or desired.

FIG. 9B is an enlarged plan view of the area CC′ of FIG. 4.

Referring to FIGS. 9A and 9B, the second sensing electrode 220 may include a first-second line 220p1 extending in the first direction DR1, and a second-second line 220p2 extending in the second direction DR2. According to an embodiment, the first-second line 220p1 and the second-second line 220p2 may not overlap with the connection pattern 212.

The connection pattern 212 may be disposed at (e.g., in or on) a layer different from that of the second sensing electrode 220 and the sensing patterns 211. The connection pattern 212 may be electrically connected to the sensing patterns 211. The connection pattern 212 may overlap with the second sensing electrode 220 when viewed in the plane (e.g., in a plan view), and the connection pattern 212 and the second sensing electrode 220 may be insulated from each other.

The connection pattern 212 may further include a first cross line 212c electrically connected to the first connection line 212p1 and the second connection line 212p2, and extending in a first cross direction CDR1 different from the first direction DR1 and the second direction DR2. The first cross line 212c may overlap with the second sensing electrode 220.

When viewed in the plane (e.g., in a plan view), the second sensing electrode 220 may not overlap with the first connection line 212p1 and the second connection line 212p2, and the second sensing electrode 220 may be provided with an opening 220op defined therethrough and overlapping with the first connection line 212p1 and the second connection line 212p2.

The second sensing electrode 220 may further include a second cross line 220c electrically connected to the first-second line 220p1 and the second-second line 220p2, and extending in a second cross direction CDR2 crossing (e.g., intersecting) the first cross direction CDR1. When viewed in the plane (e.g., in a plan view), the first cross line 212c may overlap with the second cross line 220c.

According to an embodiment, the sensing patterns 211 may include mesh lines extending in the first direction DR1 and the second direction DR2. At least one of the connection pattern 212 or the second sensing electrode 220, which receive different signals from each other, may extend in a direction different from the first direction DR1 and the second direction DR2 in an area where the connection pattern 212 and the second sensing electrode 220 overlap with each other when viewed in the plane (e.g., in a plan view). Accordingly, a portion where two lines extending in the first direction DR1 overlap with each other, or a portion where two lines extending in the second direction DR2 overlap with each other may be removed. In this case, a dispersion of the overlapping area caused by the overlapping of the two lines extending in the same direction may be reduced or eliminated. Accordingly, variations in sensing sensitivity due to a difference in a parasitic capacitance caused by the dispersion of the overlapping area may be eliminated, minimized, or reduced.

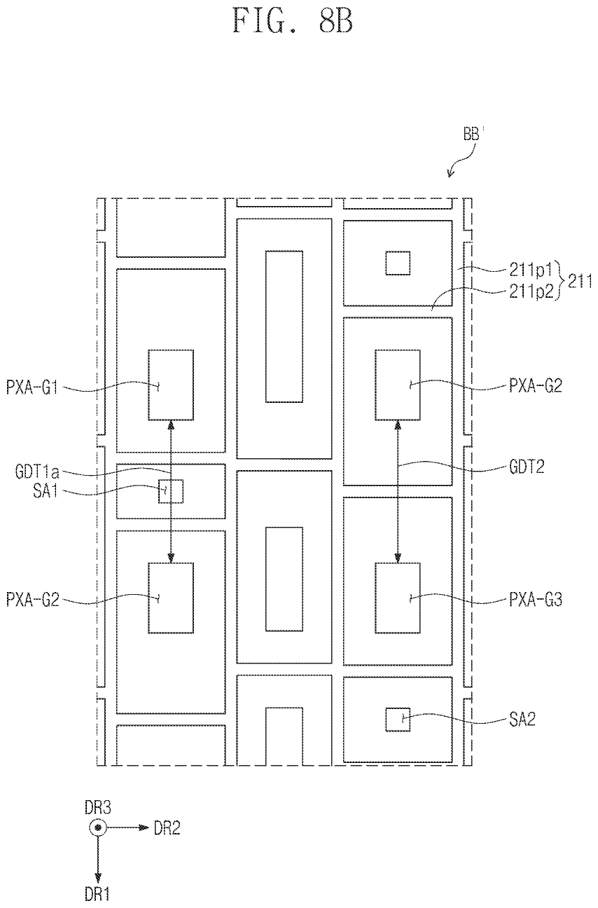

FIG. 10 is an enlarged plan view of the area DD′ of FIGS. 9A and 9B.

Referring to FIGS. 9A, 9B, and 10, a first portion 212sp1 of the connection pattern 212 and a second portion 220sp1 of the second sensing electrode 220 may be disposed between the second-second light emitting area PXA-G2 and the first sensing area SA1, which are adjacent to each other in the first direction DR1. Each of the first portion 212sp1 of the connection pattern 212 and the second portion 220sp1 of the second sensing electrode 220 may extend in the second direction DR2. When viewed in the plane (e.g., in a plan view), the first portion 212sp1 of the connection pattern 212 and the second portion 220sp1 of the second sensing electrode 220 may be spaced apart from each other.

A first distance SDT1 between the first portion 212sp1 of the connection pattern 212 and the second portion 220sp1 of the second sensing electrode 220 may be different from a second distance SDT2 between a third portion 212sp2 of the connection pattern 212 and a fourth portion 220sp2 of the second sensing electrode 220, which are disposed between the second-second light emitting area PXA-G2 and the third-second light emitting area PXA-G3.

When viewed in the plane (e.g., in a plan view), a third distance SDT3 between a fifth portion 212sp3 of the connection pattern 212 and a sixth portion 220sp3 of the second sensing electrode 220, which are disposed between one first light emitting area PXA-R from among the first light emitting areas PXA-R and one third light emitting area PXA-B from among the third light emitting areas PXA-B, may be different from at least one of the first distance SDT1 or the second distance SDT2.

FIG. 10 shows a structure in which the first distance SDT1 is the smallest and the second distance SDT2 is the greatest as a representative example, but the present disclosure is not particularly limited thereto. In other embodiments, each of the first distance SDT1, the second distance SDT2, and the third distance SDT3 may be variously modified by taking into account a desired performance of the sensor layer 200 (e.g., refer to FIG. 4), or an area of an upper surface of the pixel definition layer PDL (e.g., refer to FIG. 6A).

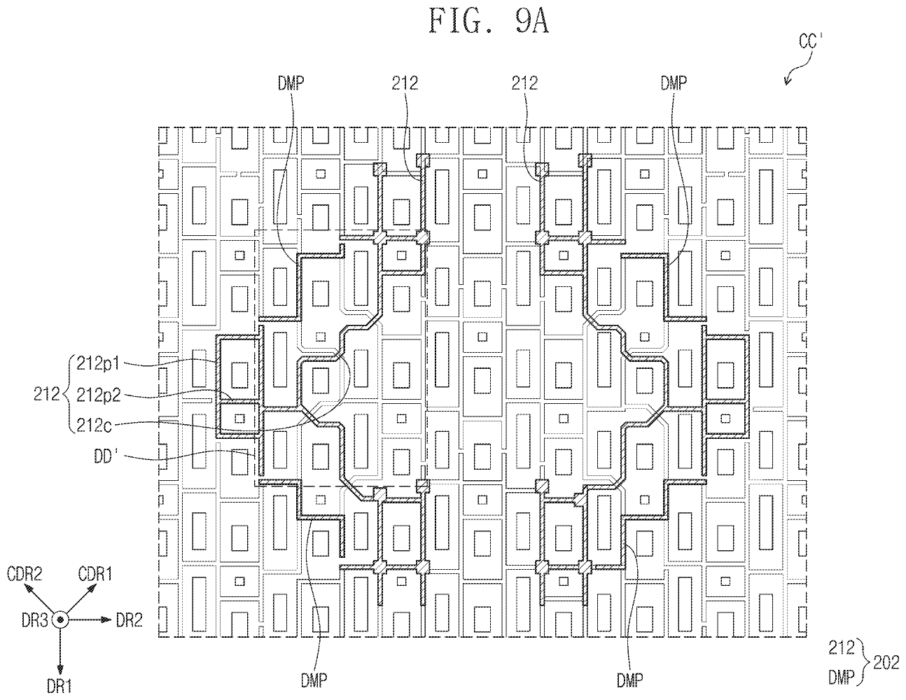

FIG. 11 is an enlarged plan view of the area EE′ of FIG. 10 according to an embodiment of the present disclosure.

Referring to FIG. 11, an angle AG between the first cross line 212c and the second cross line 220c may be equal to or greater than about 45 degrees, and equal to or smaller than about 135 degrees. As an example, an angle between the first direction DR1 and the second direction DR2 may be about 90 degrees, an angle between the first cross direction CDR1 and the second direction DR2 may be about 45 degrees, and an angle between the first cross direction CDR1 and the second cross direction CDR2 may be about 90 degrees. According to an embodiment, the first connection line 212p1, the second connection line 212p2, the first cross line 212c, the first-second line 220p1, the second-second line 220p2, and the second cross line 220c may have the same or substantially the same width as each other. As an example, the width LWT1 of the first-second line 220p1 and the width LWT2 of the first cross line 212c may be the same or substantially the same as each other. As used herein, the width may refer to a width in a direction perpendicular to or substantially perpendicular to the extension direction of the corresponding line.

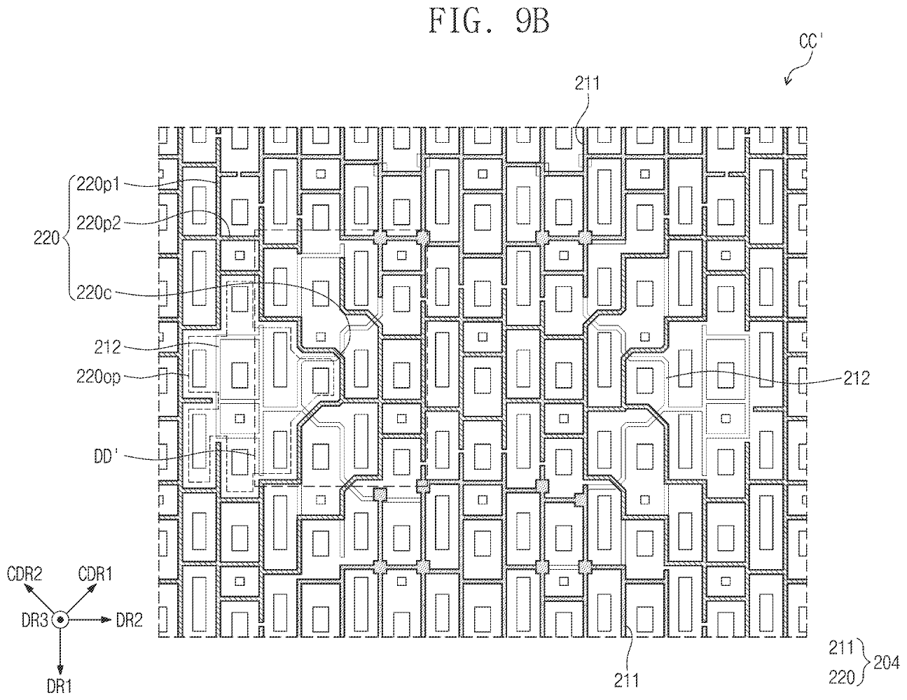

FIG. 12 is an enlarged plan view of the area EE′ of FIG. 10 according to an embodiment of the present disclosure.

Referring to FIG. 12, one or more of a first connection line 212p1, a second connection line 212p2, a first cross line 212ca, a first-second line 220p1, a second-second line 220p2, and a second cross line 220c may have a width different from that of the others.

As an example, a width LWT2a of the first cross line 212ca may be smaller than a width LWT1 of each of the first connection line 212p1, the second connection line 212p2, the first-second line 220p1, the second-second line 220p2, and the second cross line 220c. In other words, an area of a portion where the first cross line 212ca crosses the second cross line 220c may be reduced.

According to an embodiment, the second cross line 220c may have the reduced width (e.g., the width LWT2a), like that of the first cross line 212ca. According to an embodiment, the width of the first cross line 212ca may be the same or substantially the same as the width LWT1 of the first-second line 220p1, and the width of the second cross line 220c may be reduced (e.g., to the width LWT2a) instead.

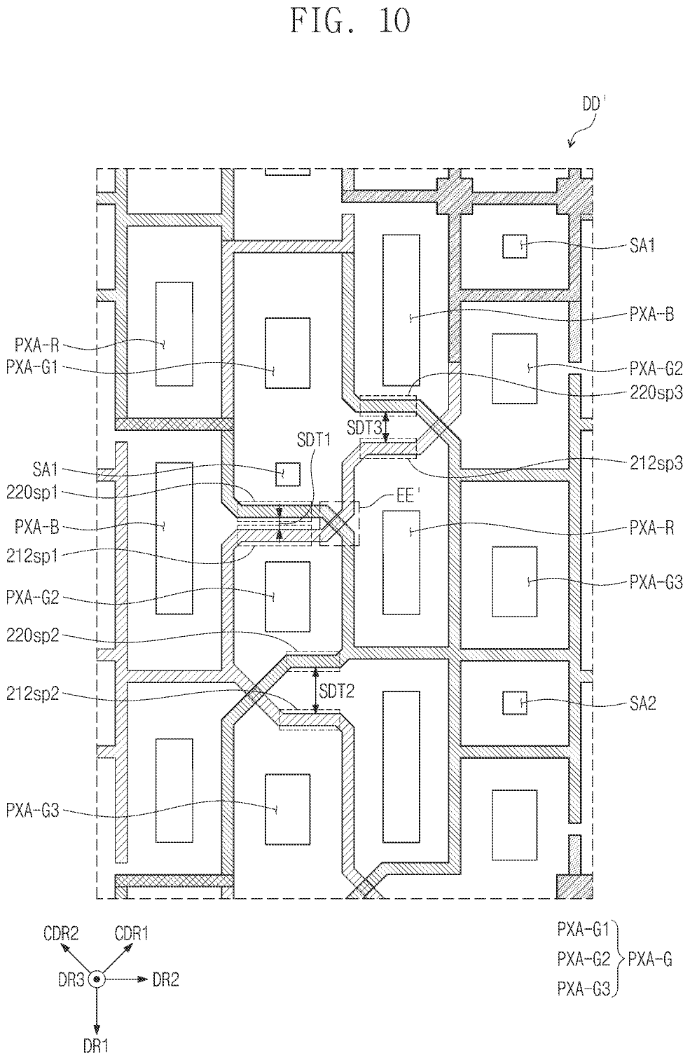

FIG. 13 is an enlarged plan view of the area EE′ of FIG. 10 according to an embodiment of the present disclosure.

Referring to FIG. 13, one or more of a first connection line 212p1, a second connection line 212p2, a first cross line 212cb, a first-second line 220p1, a second-second line 220p2, and a second cross line 220c may have a width different from that of the others.

As an example, a width LWT2b of the first cross line 212cb may be greater than a width LWT1 of each of the first connection line 212p1, the second connection line 212p2, the first-second line 220p1, the second-second line 220p2, and the second cross line 220c.

According to an embodiment, the second cross line 220c may have the increased width (e.g., the width LWT2b), like that of the first cross line 212cb. According to an embodiment, the width of the first cross line 212cb may be the same or substantially the same as the width LWT1 of the first-second line 220p1, and the width of the second cross line 220c may be increased (e.g., to the width LWT2b) instead.

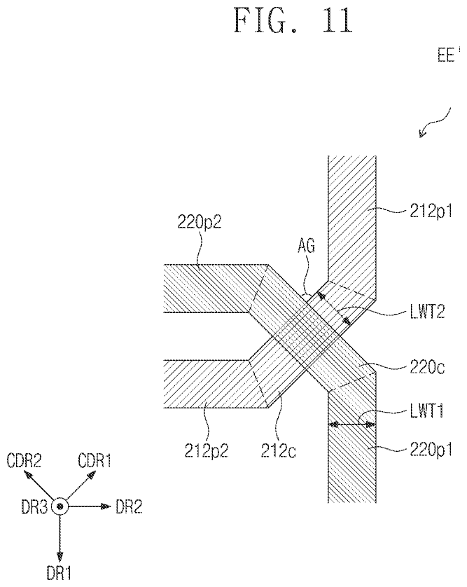

FIG. 14 is an enlarged plan view of the area EE′ of FIG. 10 according to an embodiment of the present disclosure.

Referring to FIG. 14, at least one of a first cross line 212cc or a second cross line 220c may include an overlap portion 212c-o disposed at a portion where the first cross line 212cc overlaps with and crosses the second cross line 220c, and a connection portion 212c-cn adjacent to the overlap portion 212c-o. A width LWT2c of the overlap portion 212c-o may be greater than a width of the connection portion 212c-cn.

FIG. 14 shows a structure in which the first cross line 212cc includes the overlap portion 212c-o and the connection portion 212c-cn as a representative example, but the present disclosure is not limited thereto or thereby. In another embodiment, the second cross line 220c may include the overlap portion 212c-o and the connection portion 212c-cn.

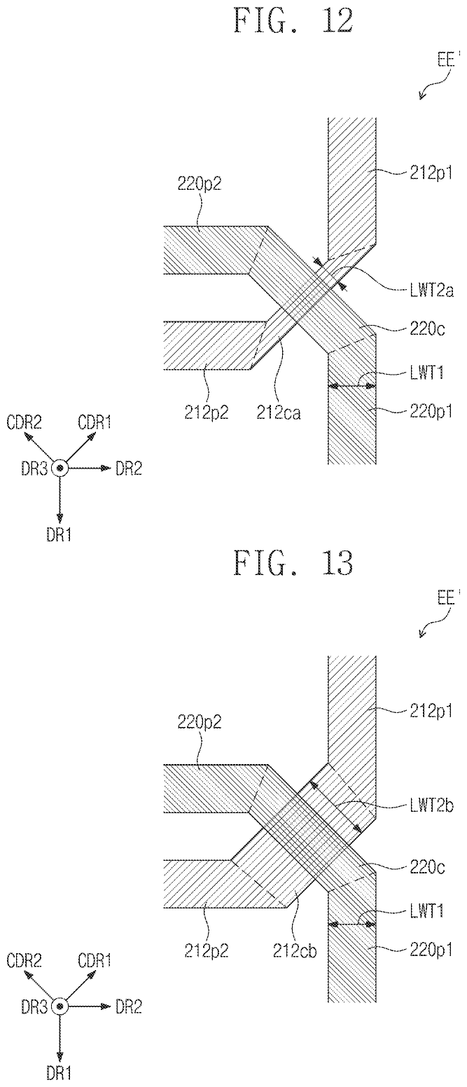

FIG. 15 is an enlarged plan view of the area EE′ of FIG. 10 according to an embodiment of the present disclosure.

Referring to FIG. 15, at least one of a first cross line 212cd or a second cross line 220c may include an overlap portion 212c-oa disposed at a portion where the first cross line 212cd overlaps with and crosses the second cross line 220c, and a connection portion 212c-cn adjacent to the overlap portion 212c-oa. A width LWT2d of the overlap portion 212c-oa may be smaller than a width of the connection portion 212c-cn.

FIG. 15 shows a structure in which the first cross line 212cd includes the overlap portion 212c-oa and the connection portion 212c-cn as a representative example, but the present disclosure is not limited thereto or thereby. In another embodiment, the second cross line 220c may include the overlap portion 212c-oa and the connection portion 212c-cn.

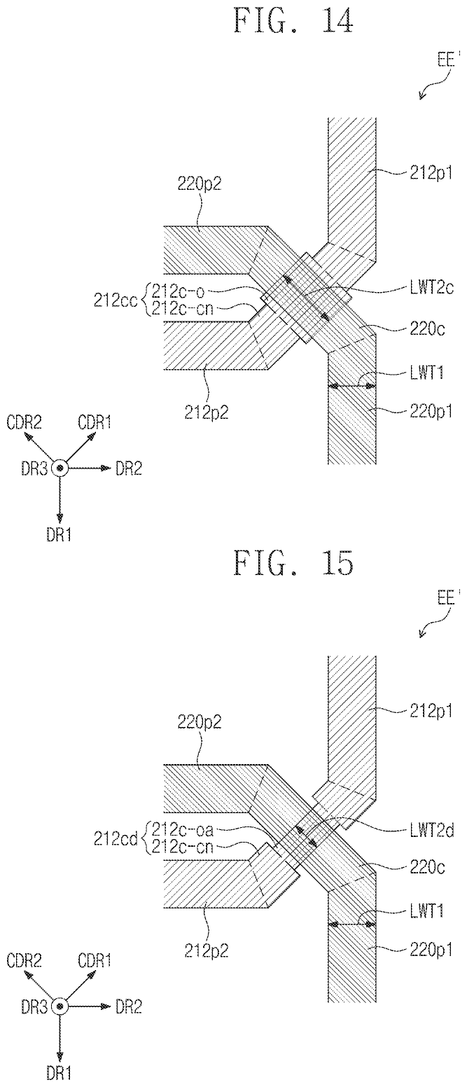

FIG. 16 is an enlarged plan view of the area EE′ of FIG. 10 according to an embodiment of the present disclosure.

Referring to FIG. 16, an angle AGa between a first cross line 212ce and a second cross line 220c may be equal to or greater than about 45 degrees, and equal to or smaller than about 135 degrees. As an example, an angle between the first direction DR1 and the second direction DR2 may be about 90 degrees, an angle between a first cross direction CDR1a and the second direction DR2 may be equal to or greater than about 0 degrees and equal to or smaller than about 90 degrees, and an angle between the second cross direction CDR2 and the second direction DR2 may be equal to or greater than about 90 degrees and equal to or smaller than about 180 degrees.

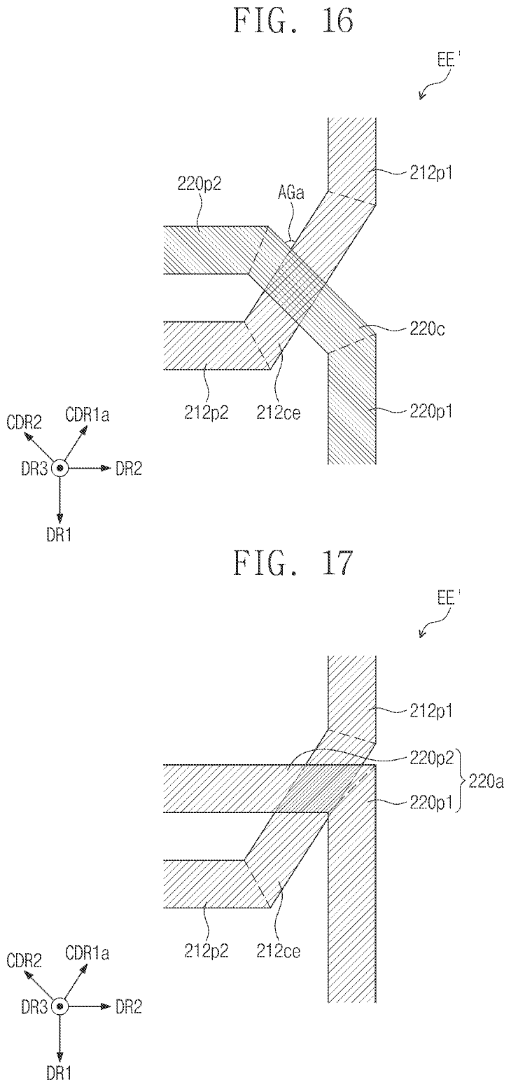

FIG. 17 is an enlarged plan view of the area EE′ of FIG. 10 according to an embodiment of the present disclosure.

Referring to FIG. 17, a second sensing electrode 220a may include a first-second line 220p1 and a second-second line 220p2. At least one of the first-second line 220p1 or the second-second line 220p2 may overlap with a first cross line 212ce.

According to embodiments of the present disclosure described above, at least one of the connection pattern 212 (e.g., refer to FIG. 4) or the second sensing electrode 220, which receive different signals from each other, may extend in the direction different from the first direction DR1 and the second direction DR2 in the area where the connection pattern 212 and the second sensing electrode 220 overlap with each other when viewed in the plane (e.g., in a plan view). Accordingly, the portion where the two lines extending in the first direction DR1 overlap with each other, or the portion where the two lines extending in the second direction DR2 overlap with each other may be removed. In this case, a dispersion of the overlapping area caused by the overlapping of the two lines extending in the same direction as each other may be reduced or eliminated. Accordingly, variations in a sensing sensitivity due to a difference in a parasitic capacitance caused by the dispersion of the overlapping area may be eliminated, minimized, or reduced.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents. is not is not

What is claimed is:

1. A display device comprising:
a display layer comprising a plurality of light emitting areas, and a plurality of sensing areas; and
a sensor layer on the display layer, and comprising:
a first sensing electrode comprising:
a plurality of sensing patterns; and
a connection pattern connected to the plurality of sensing patterns; and
a second sensing electrode,
wherein each of the plurality of sensing patterns comprises:
a first-first line extending in a first direction; and
a second-first line extending in a second direction crossing the first direction, and
wherein at least one of the connection pattern or the second sensing electrode comprises a cross line extending in a direction different from the first and second directions.

2. The display device of claim 1, wherein each of the plurality of light emitting areas and each of the plurality of sensing areas have a quadrangular shape defined by corresponding first sides extending in the first direction, and corresponding second sides extending in the second direction.

3. The display device of claim 1, wherein the plurality of light emitting areas comprises:
a plurality of first light emitting areas;
a plurality of second light emitting areas; and
a plurality of third light emitting areas,
wherein the plurality of first light emitting areas and the plurality of third light emitting areas are alternately and repeatedly located one by one along the first direction,
wherein the plurality of second light emitting areas are consecutively located along the first direction,
wherein the plurality of second light emitting areas comprise a first-second light emitting area, a second-second light emitting area, and a third-second light emitting area, which are consecutively and repeatedly located along the first direction,
wherein a first sensing area from among the plurality of sensing areas is located between the first-second light emitting area and the second-second light emitting area, and
wherein a second sensing area from among the plurality of sensing areas is located in an area spaced from the second-second light emitting area, with the third-second light emitting area interposed therebetween.

4. The display device of claim 3, wherein the first sensing area and the second sensing area are closest to each other from among the plurality of sensing areas.

5. The display device of claim 3, wherein a first distance between the first-second light emitting area and the second-second light emitting area is equal to or greater than a second distance between the second-second light emitting area and the third-second light emitting area.

6. The display device of claim 3, wherein a first portion of the connection pattern and a second portion of the second sensing electrode are located between the first sensing area and the first-second light emitting area,
wherein a third portion of the connection pattern and a fourth portion of the second sensing electrode are located between the second-second light emitting area and the third-second light emitting area,
and wherein a first distance between the first portion and the second portion is different from a second distance between the third portion and the fourth portion in a plan view.

7. The display device of claim 6, wherein a fifth portion of the connection pattern and a sixth portion of the second sensing electrode are located between one first light emitting area from among the plurality of first light emitting areas and one third light emitting area from among the plurality of third light emitting areas, and
wherein a third distance between the fifth portion and the sixth portion is different from at least one of the first distance or the second distance in a plan view.

8. The display device of claim 3, wherein the display layer comprises:
a plurality of first electrodes corresponding to the plurality of light emitting areas and the plurality of sensing areas;
a first functional layer on the plurality of first electrodes, and commonly corresponding to the plurality of light emitting areas and the plurality of sensing areas;
a plurality of light emitting layers on the first functional layer, and corresponding to the plurality of light emitting areas, respectively;
a plurality of photoelectric conversion layers on the first functional layer, and corresponding to the plurality of sensing areas, respectively;
a second functional layer on the plurality of light emitting layers and the plurality of photoelectric conversion layers, and commonly corresponding to the plurality of light emitting areas and the plurality of sensing areas; and
a second electrode on the second functional layer.

9. The display device of claim 8, wherein the display layer further comprises an auxiliary layer commonly located between the first functional layer and the light emitting layer of the first-second light emitting area, between the first functional layer and the light emitting layer of the second-second light emitting area, and between the first functional layer and the photoelectric conversion layer of the first sensing area.

10. The display device of claim 1, wherein the connection pattern comprises a first connection line extending in the first direction, and a second connection line extending in the second direction,
wherein the second sensing electrode comprises a first-second line extending in the first direction, and a second-second line extending in the second direction,
wherein the connection pattern is located at a layer different from that of the second sensing electrode and the plurality of sensing patterns,
wherein the connection pattern overlaps with the second sensing electrode in a plan view, and
wherein the connection pattern and the second sensing electrode are insulated from each other.

11. The display device of claim 10, wherein the connection pattern further comprises a first cross line electrically connected to the first connection line and the second connection line, and extending in a first cross direction different from the first and second directions, and
wherein the first cross line overlaps with the second sensing electrode in a plan view.

12. The display device of claim 11, wherein the second sensing electrode does not overlap with the first connection line and the second connection line in a plan view, and
wherein the second sensing electrode has an opening corresponding to the first connection line and the second connection line.

13. The display device of claim 11, wherein the second sensing electrode further comprises a second cross line electrically connected to the first-second line and the second-second line, and extending in a second cross direction crossing the first cross direction, and
wherein the first cross line overlaps with the second cross line in a plan view.

14. The display device of claim 13, wherein an angle between the first cross line and the second cross line is greater than or equal to about 45 degrees, and smaller than or equal to about 135 degrees.

15. The display device of claim 13, wherein at least one of the first cross line or the second cross line comprises:
an overlap portion located at a portion where the first cross line overlaps with and crosses the second cross line; and
a connection portion adjacent to the overlap portion, and
wherein the overlap portion has a width different from a width of the connection portion.

16. The display device of claim 13, wherein at least one of the first cross line or the second cross line has a width different from a width of the first connection line.

17. A display device comprising:
a display layer comprising a plurality of light emitting areas, and a plurality of sensing areas; and
a sensor layer on the display layer, and comprising:
a first sensing electrode comprising:
a plurality of sensing patterns; and
a connection pattern connected to the plurality of sensing patterns; and
a second sensing electrode,
wherein a first portion of the connection pattern and a second portion of the second sensing electrode are located between a light emitting area from among the light emitting areas and a sensing area from among the sensing areas adjacent to the light emitting area in a first direction,
wherein each of the first portion and the second portion extends in a second direction crossing the first direction, and
wherein the first portion and the second portion are spaced from each other in a plan view.

18. The display device of claim 17, wherein the connection pattern further comprises a first cross line extending from the first portion in a first cross direction crossing the first and second directions, and
wherein the first cross line overlaps with the second sensing electrode in a plan view.

19. The display device of claim 18, wherein the second sensing electrode further comprises a second cross line extending from the second portion in a second cross direction crossing the first cross direction, and
wherein the first cross line overlaps with the second cross line in a plan view.

20. The display device of claim 19, wherein an angle between the first cross line and the second cross line is greater than or equal to about 45 degrees, and smaller than or equal to about 135 degrees.

21. The display device of claim 17, wherein a third portion of the connection pattern and a fourth portion of the second sensing electrode are located between two light emitting areas that are adjacent to each other in the first direction from among the plurality of light emitting areas, and
wherein a first distance in the first direction between the first portion and the second portion is different from a second distance between the third portion and the fourth portion.

22. The display device of claim 17, wherein the plurality of light emitting areas comprises:
a plurality of first light emitting areas;
a plurality of second light emitting areas; and
a plurality of third light emitting areas,
wherein the plurality of first light emitting areas and the plurality of third light emitting areas are alternately and repeatedly located one by one along the first direction,
wherein the plurality of second light emitting areas are consecutively located along the first direction,
wherein the plurality of second light emitting areas comprise a first-second light emitting area, a second-second light emitting area, and a third-second light emitting area consecutively and repeatedly located along the first direction,
wherein a first sensing area from among the plurality of sensing areas is located between the first-second light emitting area and the second-second light emitting area, and
wherein a second sensing area from among the plurality of sensing areas is located in an area spaced from the second-second light emitting area with the third-second light emitting area interposed therebetween.

23. The display device of claim 22, wherein the display layer comprises:
a plurality of first electrodes corresponding to the plurality of light emitting areas and the plurality of sensing areas;
a first functional layer on the plurality of first electrodes, and commonly corresponding to the plurality of light emitting areas and the plurality of sensing areas;
a plurality of light emitting layers on the first functional layer, and respectively corresponding to the plurality of light emitting areas;
a plurality of photoelectric conversion layers on the first functional layer, and respectively corresponding to the plurality of sensing areas;
a second functional layer on the plurality of light emitting layers and the plurality of photoelectric conversion layers, and commonly corresponding to the plurality of light emitting areas and the plurality of sensing areas; and
a second electrode on the second functional layer.

24. The display device of claim 23, wherein the display layer further comprises an auxiliary layer commonly located between the first functional layer and the light emitting layer of the first-second light emitting area, between the first functional layer and the light emitting layer of the second-second light emitting area, and between the first functional layer and the photoelectric conversion layer of the first sensing area.
